(19) United States
(12) Patent Application Publication
(10) Pub. No.: US 2026/0019037 A1
(43) Pub. Date: Jan. 15, 2026

(54) TRACKER CIRCUIT, COMMUNICATION DEVICE, AND VOLTAGE SUPPLY METHOD

(71) Applicant: Murata Manufacturing Co., Ltd., Nagaokakyo-shi (JP)

(72) Inventors: Atsuya HIRONO, Nagaokakyo-shi (JP); Takeshi Kogure, Nagaokakyo-shi (JP); Taichi Yamaguchi, Nagaokakyo-shi (JP); Naohide Tomita, Nagaokakyo-shi (JP)

(21) Appl. No.: 19/334,118

(22) Filed: Sep. 19, 2025

Related U.S. Application Data
(63) Continuation of application No. PCT/JP2024/006717, filed on Feb. 26, 2024.

(30) Foreign Application Priority Data
Mar. 27, 2023 (JP) 2023-050455

(51) Int. Cl. H03F 1/02; H02M 3/07; H02M 3/156; H03F 3/24

(52) U.S. Cl. CPC H03F 1/0227; H02M 3/07; H02M 3/156; H03F 3/245; H03F 2200/102; H03F 2200/105; H03F 2200/451

(57) ABSTRACT

A tracker circuit is provided that includes a pre-regulator circuit, a switched-capacitor circuit, a supply modulator, and a selector switch circuit. The pre-regulator circuit is configured to convert an input voltage into a regulated voltage. The switched-capacitor circuit includes a plurality of input terminals that receive the input voltage and the regulated voltage. The switched-capacitor circuit generates a plurality of discrete voltages. The supply modulator selectively outputs at least one of the plurality of discrete voltages to a power amplifier. The selector switch circuit selects one of the plurality of input terminals and outputs the input voltage to the selected input terminal. The selector switch circuit also selects an other input terminal and outputs the regulated voltage to the other input terminal.

### CROSS REFERENCE TO RELATED APPLICATIONS

This application is a continuation of International Application No. PCT/JP2024/006717, filed Feb. 26, 2024, which claims priority to Japanese Patent Application No. Application No. 2023-050455, filed Mar. 27, 2023, the contents of each of which are hereby incorporated by reference in their entireties.

### TECHNICAL FIELD

The present disclosure relates to a tracker circuit, a communication device, and a voltage supply method.

### BACKGROUND

Envelope tracking (ET) has been used in recent years for power amplifiers to improve power-added efficiency. For example, U.S. Pat. No. 8,829,993 discloses a digital envelope tracking (D-ET) technique that selectively supplies a plurality of discrete voltages based on an envelope signal.

For the D-ET mode, however, a further improvement in power-added efficiency is desired.

### SUMMARY OF THE INVENTION

Accordingly, the exemplary aspects of the present disclosure provide a tracker circuit, a communication device, and a voltage supply method that improve power-added efficiency in the D-ET mode.

In an exemplary aspect, a tracker circuit is provided that includes a converter circuit, a switched-capacitor circuit, a supply modulator, and a selector switch circuit. The converter circuit is configured to convert an input voltage into a regulated voltage. The switched-capacitor circuit includes a plurality of first input terminals that receive the input voltage and the regulated voltage. The switched-capacitor circuit is configured to generate and output a plurality of discrete voltages. The supply modulator is configured to selectively output at least one of the plurality of discrete voltages to a power amplifier. The selector switch circuit is connected to the converter circuit and the switched-capacitor circuit. The selector switch circuit is configured to select one of the plurality of first input terminals and output the input voltage to the one of the plurality of first input terminals, and is configured to select an other one of the plurality of input terminals and output the regulated voltage to the other one of the plurality of first input terminals.

In another exemplary aspect, a tracker circuit is provided that includes a converter circuit, a selector switch circuit, a switched-capacitor circuit, and a supply modulator. The converter circuit includes a fourth input terminal that receives an input voltage, and a first output terminal that outputs a regulated voltage generated from the input voltage. The selector switch circuit includes a second input terminal connected to the fourth input terminal, a third input terminal connected to the first output terminal, and a plurality of second output terminals. The switched-capacitor circuit includes a plurality of first input terminals connected one-to-one to the plurality of second output terminals, and a plurality of third output terminals that are connected one-to-one to the plurality of first input terminals, and that output a plurality of discrete voltages generated based on the input voltage and the regulated voltage. The supply modulator includes a plurality of fifth input terminals connected one-to-one to the plurality of third output terminals, and a fourth output terminal connected to a power amplifier.

In yet another exemplary aspect, a communication device is provided that includes the tracker circuit according to the above-mentioned aspect, a signal processing circuit, and a radio frequency circuit. The signal processing circuit is configured to process a radio frequency signal. The radio frequency circuit includes the power amplifier and is configured to transmit the radio frequency signal between the signal processing circuit and an antenna.

Moreover, in an exemplary aspect, a voltage supply method is provided that includes converting an input voltage into a regulated voltage; selecting one of a plurality of input terminals of the switched-capacitor circuit and outputting the input voltage to the one of the plurality of input terminals, and selecting an other one of the plurality of input terminals and outputting the regulated voltage to the other one of the plurality of input terminals; by the switched-capacitor circuit, generating a plurality of discrete voltages based on the input voltage and the regulated voltage; and selectively outputting at least one of the plurality of discrete voltages to a power amplifier.

A tracker circuit according to an exemplary aspect of the present disclosure provides for improved power-added efficiency in the D-ET mode.

### BRIEF DESCRIPTION OF DRAWINGS

FIG. 1A is a graph illustrating an example of changes in power supply voltage in an average power tracking (APT) mode.

FIG. 1B is a graph illustrating an example of changes in power supply voltage in an analog envelope tracking (A-ET) mode.

FIG. 1C is a graph illustrating an example of changes in power supply voltage in a D-ET mode.

FIG. 2 is a circuit diagram of a communication device according to Exemplary Embodiment 1.

FIG. 3 is a circuit diagram of a tracker circuit according to Exemplary Embodiment 1.

FIG. 4 is a flowchart illustrating a voltage supply method according to Exemplary Embodiment 1.

FIG. 5 is a graph illustrating a plurality of levels of power supply voltages that can be output by the tracker circuit according to Exemplary Embodiment 1, and the power supply voltage to be supplied to a power amplifier.

FIG. 6A is a circuit diagram illustrating a first example of a connection configuration for a selector switch circuit according to Exemplary Embodiment 1.

FIG. 6B is a circuit diagram illustrating a first example of a connection configuration for the selector switch circuit according to Exemplary Embodiment 1.

FIG. 6C is a circuit diagram illustrating a second example of a connection configuration for the selector switch circuit according to Exemplary Embodiment 1.

FIG. 6D is a circuit diagram illustrating a third example of a connection configuration for the selector switch circuit according to Exemplary Embodiment 1.

FIG. 7 is a circuit diagram of a tracker circuit according to Exemplary Embodiment 2.

FIG. 8A is a circuit diagram illustrating an example of a connection configuration for the selector switch circuit according to Embodiment 2.

FIG. 8B is a circuit diagram illustrating an example of a connection configuration for the selector switch circuit according to Exemplary Embodiment 2.

FIG. 9 is a circuit diagram of a tracker circuit according to Exemplary Embodiment 3.

FIG. 10A is a circuit diagram illustrating a first example of a connection configuration for the selector switch circuit according to Exemplary Embodiment 3.

FIG. 10B is a circuit diagram illustrating a first example of a connection configuration for the selector switch circuit according to Exemplary Embodiment 3.

FIG. 11 is a plan view of an example of arrangement of switch portions included in the tracker circuit according to the exemplary embodiments.

FIG. 12 is a plan view of another example of arrangement of switch portions included in the tracker circuit according to the exemplary embodiments.

### DETAILED DESCRIPTION OF EMBODIMENTS

Exemplary embodiments of the present disclosure will now be described in detail below with reference to the drawings. Embodiments described below each represent generic or specific examples. Features presented in the following embodiments, such as numerical values, shapes, materials, constituent elements, and the positioning and connection of constituent elements, are illustrative only and not intended to be limiting of the exemplary aspects of the present disclosure.

The drawings are schematic in nature with emphases, omissions, or proportion adjustments made as necessary to illustrate the exemplary aspects of the present disclosure, and do not necessarily represent exact details. Accordingly, the illustrated shapes, positional relationships, and proportions may differ from the actuality. Throughout the drawings, identical reference signs are used to designate substantially identical structural features, and repetitive description will be sometimes omitted or simplified.

As used in the description of circuit configurations, expressions such as “connected” include not only cases where circuit elements are directly connected by a connection terminal and/or a wiring conductor, but also cases where circuit elements are electrically connected with another circuit element interposed therebetween. Expressions such as “directly connected” can indicate that circuit elements are directly connected by a connection terminal and/or a wiring conductor with no other circuit element interposed therebetween. Expressions such as “C is connected between A and B” can indicate that C is connected at one end to A and connected at the other end to B and can indicate mean that C is connected in series with a path that connects A and B to each other. Expressions such as “path that connects A and B to each other” can refer to a path formed by a conductor that electrically connects A to B.

As used in the following description, expressions such as “terminal” refer to a point where a conductor within an element terminates. In an exemplary aspect, when the impedance of a conductor located between elements is sufficiently low, a terminal is interpreted not only as a single point, but also as any given point on the conductor located between the elements or as the entire conductor.

Further, “parallel”, “perpendicular”, or other such expressions indicative of the relationship between elements, and “rectangular” or other such expressions indicative of a shape of an element, as well as numerical ranges are not intended to represent only their strict meanings but are meant to also include their substantial equivalents with a margin of error of, for example, about several percent.

As used herein, unless otherwise noted, an ordinal number such as “first” or “second” is not intended to indicate the number or order of constituent elements but used for the purpose of avoiding confusion and distinguishing between constituent elements of the same kind.

### (Tracking Modes)

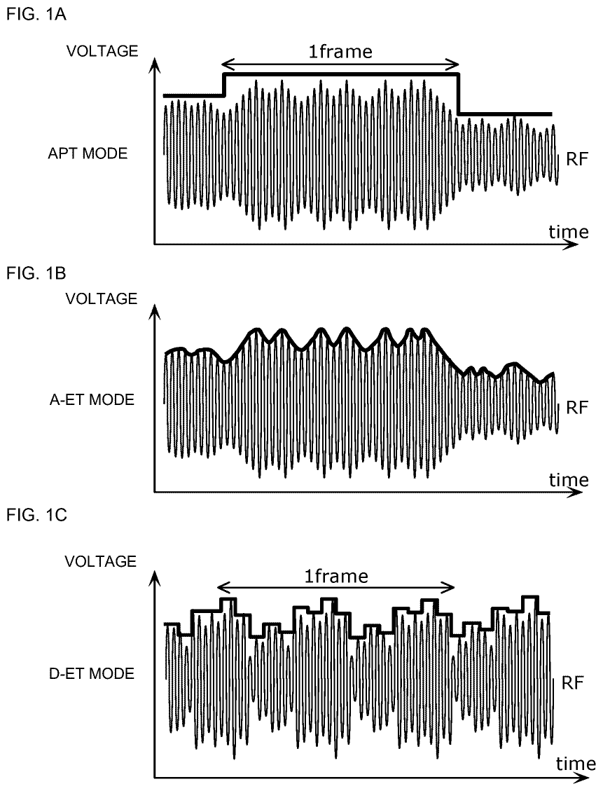

First, as a technique for efficiently amplifying a radio frequency signal, tracking modes are described below in which a power amplifier receives supply of a power supply voltage that is dynamically adjusted with the passage of time based on the radio frequency signal. A tracking mode refers to a mode that dynamically adjusts the power supply voltage to be applied to a power amplifier. Several types of tracking modes exist, of which APT, A-ET, and D-ET modes will now be described with reference to FIGS. 1A to 1C. In FIGS. 1A to 1C, the horizontal axis represents time, and the vertical axis represents voltage. A thick solid line represents power supply voltage, and a thin solid line (e.g., waveform) represents modulated signal.

FIG. 1A is a graph illustrating an example of changes in power supply voltage in the APT mode. In the APT mode, the power supply voltage is varied across a plurality of discrete voltage levels in units of one frame based on average power.

In an exemplary aspect, a frame refers to a unit forming a radio frequency signal (e.g., a modulated signal). For example, in 5th Generation New Radio (5GNR) and Long Term Evolution (LTE), a frame includes ten subframes. Each subframe includes a plurality of slots. Each slot includes a plurality of symbols. A subframe has a length of 1 ms, and a frame has a length of 10 ms.

A mode in which the voltage level is varied in units of one frame or in larger units based on average power is referred to as “APT mode”, which is distinguished from a mode in which the voltage level is varied in units smaller than one frame (e.g., in units of subframes, slots, or symbols).

FIG. 1B is a graph illustrating an example of changes in power supply voltage in the A-ET mode. In the A-ET mode, the power supply voltage is varied continuously based on an envelope signal to thus track the envelope of a modulated signal.

An envelope signal is a signal representing the envelope of a modulated signal. An envelope value is expressed as, for example, the square root of (I²+Q²). In this case, (I, Q) represents a constellation point. A constellation point is a point representing, on a constellation diagram, a signal modulated by digital modulation. The value (I, Q) is determined by, for example, a baseband integrated circuit (BBIC) based on, for example, transmission information.

FIG. 1C is a graph illustrating an example of changes in power supply voltage in the D-ET mode. In the D-ET mode, the power supply voltage is varied across a plurality of discrete voltage levels within one frame based on an envelope signal to thus track the envelope of a modulated signal. That is, in D-ET, the power supply voltage varies at shorter time intervals than in APT.

### Exemplary Embodiment 1

Exemplary Embodiment 1 will now be described.

### 1.1 Circuit Configuration of Communication Device 7

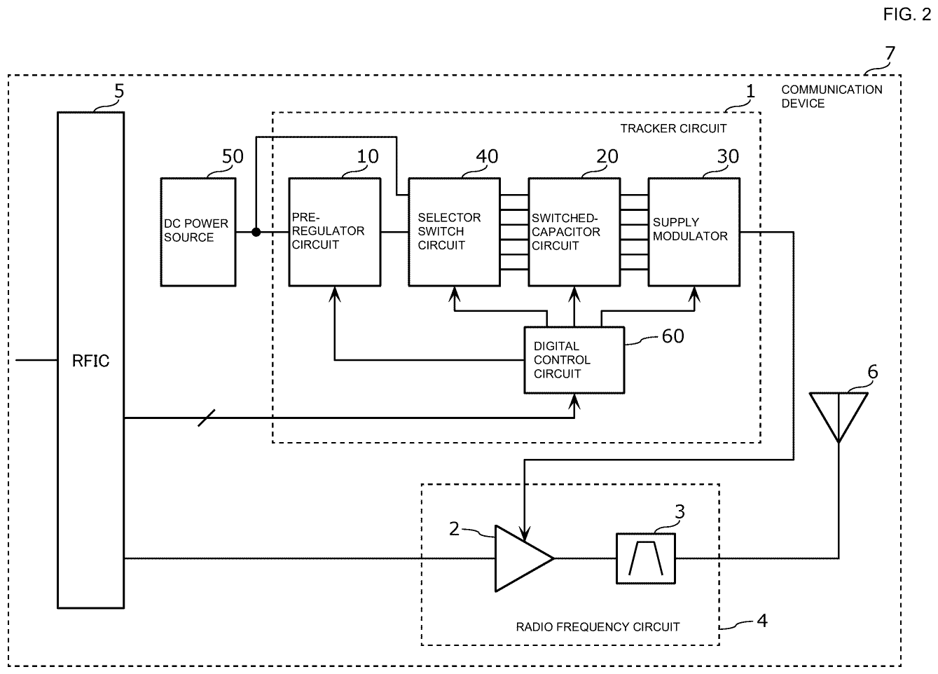

First, a communication device 7 according to Embodiment 1 will be described with reference to FIG. 2. FIG. 2 is a circuit diagram of the communication device 7 according to Embodiment 1.

FIG. 2 illustrates an exemplary circuit configuration. The communication device 7 may be implemented by using any one of a wide variety of circuit implementations and circuit technologies. Therefore, the description of the communication device 7 provided below is not to be construed restrictively.

The communication device 7 according to Embodiment 1 corresponds to user equipment (UE) in a cellular network (also referred to as “mobile network”), typical examples of which include a mobile phone, a smartphone, a tablet computer, and a wearable device. The communication device 7 may be an Internet of Things (IoT) sensor device, a medical/healthcare device, a vehicle, an unmanned aerial vehicle (UAV) (a so-called drone), or an automated guided vehicle (AGV). The communication device 7 may also be configured as a base station (BS) in a cellular network.

As illustrated in FIG. 2, the communication device 7 includes a tracker circuit 1, a radio frequency circuit 4, a radio frequency integrated circuit (RFIC) 5, an antenna 6, and a direct current (DC) power source 50.

The tracker circuit 1 is configured to supply a plurality of discrete voltages to a power amplifier 2 in the D-ET mode. Further, the tracker circuit 1 may be configured to supply the discrete voltages to the power amplifier 2 in the APT mode. As illustrated in FIG. 2, the tracker circuit 1 includes a pre-regulator circuit 10, a switched-capacitor circuit 20, a supply modulator 30, a selector switch circuit 40, and a digital control circuit 60.

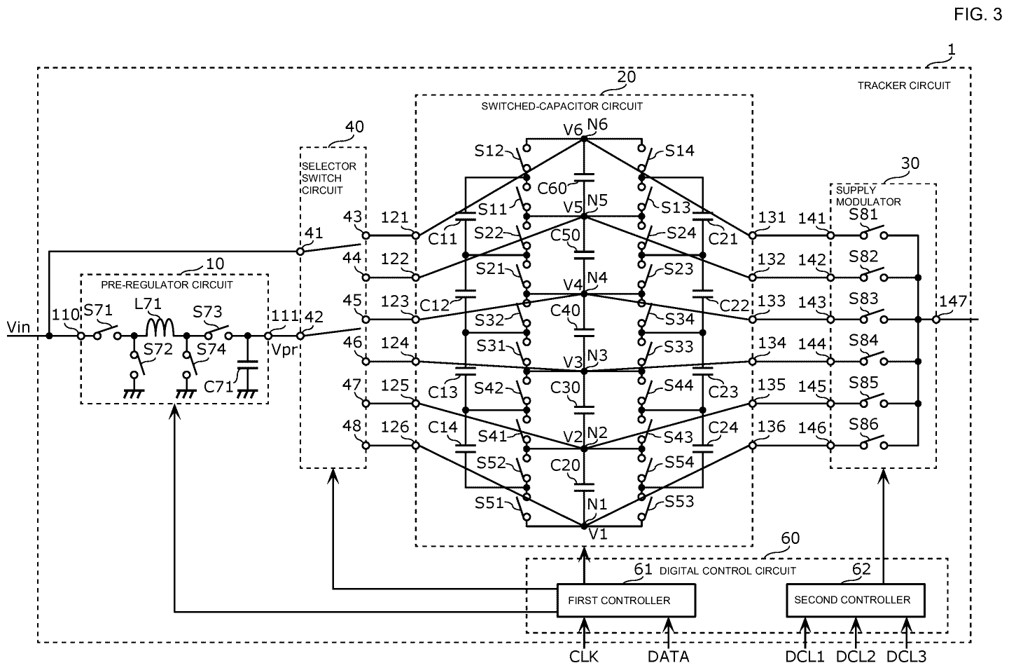

The pre-regulator circuit 10 is an example of a converter circuit. The pre-regulator circuit 10 may sometimes be also referred to as “magnetic regulator” or “DC-DC converter”. The pre-regulator circuit 10 is configured to convert an input voltage into a regulated voltage. According to Embodiment 1, the pre-regulator circuit 10 is a one-input, one-output buck-boost converter. The pre-regulator circuit 10 is configured to receive an output voltage from the DC power source 50 as the input voltage, converting the received input voltage into the regulated voltage, and outputting the resulting regulated voltage as the input voltage for the selector switch circuit 40. The pre-regulator circuit 10 is vary the magnitude of the regulated voltage based on, for example, a control signal provided from the RFIC 5. The circuit configuration of the pre-regulator circuit 10 will be described later with reference to FIG. 3.

The switched-capacitor circuit 20 is configured to generate and output the discrete voltages. According to Embodiment 1, the switched-capacitor circuit 20 is configured to generate and output the discrete voltages based on the following voltages: the input voltage supplied from the DC power source 50 via the selector switch circuit 40; and the regulated voltage supplied from the pre-regulator circuit 10 via the selector switch circuit 40. Specifically, the switched-capacitor circuit 20 is configured to generate and output the discrete voltages based on the difference between the input voltage and the regulated voltage. More specifically, the switched-capacitor circuit 20 generates and outputs the discrete voltages including the following voltages: a first output voltage based on the input voltage; a second output voltage based on the regulated voltage; and a third output voltage based on the difference between the input voltage and the regulated voltage. For example, the switched-capacitor circuit 20 is configured to generate the discrete voltages including the following voltages: the first output voltage equal to the input voltage; the second output voltage equal to the regulated voltage; and the third output voltage higher than one of the first output voltage or the second output voltage and lower than the other of the first output voltage or the second output voltage. The circuit configuration of the switched-capacitor circuit 20 will be described later with reference to FIG. 3.

The supply modulator 30 is configured to receive the discrete voltages from the switched-capacitor circuit 20. Specifically, the supply modulator 30 is configured to selectively output at least one of the discrete voltages to the power amplifier 2. That is, the supply modulator 30 is configured to select at least one voltage from the discrete voltages and supply the selected voltage to the power amplifier 2. The circuit configuration of the supply modulator 30 will be described later with reference to FIG. 3.

The selector switch circuit 40 is connected to the pre-regulator circuit 10 and the switched-capacitor circuit 20. The selector switch circuit 40 is configured to select one input terminal of a plurality of input terminals of the switched-capacitor circuit 20 and output, to the one input terminal, the input voltage for the tracker circuit 1, and configured to select another input terminal and output, to the other input terminal, the regulated voltage provided from the pre-regulator circuit 10. The circuit configuration of the selector switch circuit 40 will be described later with reference to FIG. 3.

The digital control circuit 60 is configured to control, based on digital control signals provided from the RFIC 5, the pre-regulator circuit 10, the switched-capacitor circuit 20, the supply modulator 30, and the selector switch circuit 40. Specifically, the digital control circuit 60 is configured to generate and output the following control signals: a control signal for controlling switches included in the pre-regulator circuit 10; a control signal for controlling switches included in the switched-capacitor circuit 20; a control signal for controlling switches included in the supply modulator 30; and a control signal for controlling switches included in the selector switch circuit 40. The circuit configuration of the digital control circuit 60 will be described later with reference to FIG. 3. The tracker circuit 1 may be configured to not include the digital control circuit 60.

The DC power source 50 is configured to supply a DC voltage to the pre-regulator circuit 10. A suitable non-limiting example of the DC power source 50 is a rechargeable battery. According to Embodiment 1, the DC voltage output by the DC power source 50 is the input voltage for the tracker circuit 1.

The radio frequency circuit 4 is configured to transmit a radio frequency signal between the RFIC 5 and the antenna 6. As illustrated in FIG. 2, the radio frequency circuit 4 includes the power amplifier 2 and a filter 3.

The power amplifier 2 is connected between the RFIC 5 and the filter 3. Further, the power amplifier 2 is connected to the tracker circuit 1. The power amplifier 2 is configured to amplify a radio frequency signal received from the RFIC 5, by using the power supply voltage (i.e., discrete voltages) received from the tracker circuit 1.

The filter 3 is connected between the power amplifier 2 and the antenna 6. The filter 3 is a band pass filter with a passband that includes a predetermined band. The radio frequency circuit 4 may be configured to not include the filter 3.

The predetermined band is a frequency band for communication systems built by using radio access technology (RAT). The predetermined band is predefined by standardizing bodies or other entities (such as 3rd Generation Partnership Project (3GPP) (registered trademark) and Institute of Electrical and Electronics Engineers (IEEE)). Examples of such communication systems include 5GNR systems, LTE systems, and Wireless Local Area Network (WLAN) systems.

The RFIC 5 is an example of a signal processing circuit configured to process a radio frequency signal. The RFIC 5 is connected to an input terminal of the power amplifier 2. The RFIC 5 performs signal processing such as up-conversion on a transmission signal input from the BBIC (not illustrated), and outputs a radio frequency transmission signal generated through the signal processing to a transmission path (specifically, the power amplifier 2) of the radio frequency circuit 4.

Further, the RFIC 5 is an example of a control circuit, and includes a control unit to control the tracker circuit 1, the power amplifier 2, and other components. For example, the RFIC 5 outputs an envelope signal of a radio frequency input signal obtained from the BBIC to the tracker circuit 1. The envelope signal is used in selecting a voltage to be output by the tracker circuit 1.

It should be appreciated that some or all of the functions of the RFIC 5 as a control unit may be provided outside the RFIC 5, for example, in the BBIC or the tracker circuit 1. For example, the above-mentioned control function for selecting the power supply voltage may be included not in the RFIC 5 but in the tracker circuit 1.

The antenna 6 transmits a radio frequency signal input from the radio frequency circuit 4. The communication device 7 may be configured to not include the antenna 6.

The circuit configuration of the communication device 7 in FIG. 2 is illustrative and not intended to be limiting. For example, the communication device 7 may include a baseband signal processing circuit (BBIC) that performs signal processing by using an intermediate frequency band lower than the frequency band of the radio frequency signal.

### 1.2 Circuit Configuration of Tracker Circuit 1

The circuit configuration of the tracker circuit 1 will now be described with reference to FIG. 3. FIG. 3 is a circuit diagram of the tracker circuit 1 according to Embodiment 1.

FIG. 3 illustrates an exemplary circuit configuration. The tracker circuit 1 may be implemented by using any one of a wide variety of circuit implementations and circuit technologies. Accordingly, the description of the tracker circuit 1 provided below is not to be construed restrictively.

As described above, the tracker circuit 1 includes the pre-regulator circuit 10, the switched-capacitor circuit 20, the supply modulator 30, the selector switch circuit 40, and the digital control circuit 60. The tracker circuit 1 may include a filter circuit (not illustrated) provided between the supply modulator 30 and the power amplifier 2. Omitting the filter circuit as in FIG. 3 achieves miniaturization of the tracker circuit 1.

The pre-regulator circuit 10, the selector switch circuit 40, the switched-capacitor circuit 20, the supply modulator 30, and the digital control circuit 60 are described below in this order with regard to their respective circuit configurations.

### 1.2.1 Circuit Configuration of Pre-Regulator Circuit 10

First, the circuit configuration of the pre-regulator circuit 10 is described below with reference to FIG. 3.

As illustrated in FIG. 3, the pre-regulator circuit 10 includes an input terminal 110, an output terminal 111, switches S71 to S74, a power inductor L71, and a capacitor C71.

The input terminal 110 is an example of a fourth input terminal that receives the input voltage (Vin). Specifically, the input terminal 110 receives, as the input voltage (Vin), a DC voltage from the DC power source 50. The input terminal 110 is connected outside the pre-regulator circuit 10 to an output terminal (not illustrated) of the DC power source 50 and connected inside the pre-regulator circuit 10 to the switch S71.

The output terminal 111 is an example of a first output terminal that outputs the regulated voltage generated from the input voltage (Vin). The output terminal 111 is a terminal for supplying the regulated voltage to the selector switch circuit 40. The output terminal 111 is connected outside the pre-regulator circuit 10 to an input terminal 42 of the selector switch circuit 40 and connected inside the pre-regulator circuit 10 to the switch S73.

The power inductor L71 is an inductor used to step up and step down a DC voltage. One end of the power inductor L71 is connected to the switches S71 and S72, and the other end of the power inductor L71 is connected to the switches S73 and S74.

The switch S71 is connected between the input terminal 110 and the one end of the power inductor L71. With the connection configuration mentioned above, the switch S71 is switched between open and closed states to allow switching between connection and disconnection between the input terminal 110 and the one end of the power inductor L71.

The switch S72 is connected between the one end of the power inductor L71 and ground. With the connection configuration mentioned above, the switch S72 is switched between open and closed states to allow switching between connection and disconnection between the one end of the power inductor L71 and ground.

The switch S73 is connected between the other end of the power inductor L71 and the output terminal 111. With the connection configuration mentioned above, the switch S73 is switched between open and closed states to allow switching between connection and disconnection between the other end of the power inductor L71 and the output terminal 111.

The switch S74 is connected between the other end of the power inductor L71 and ground. With the connection configuration mentioned above, the switch S74 is switched between open and closed states to allow switching between connection and disconnection between the other end of the power inductor L71 and ground.

The capacitor C71 is connected between ground and a path connecting the switch S73 and the output terminal 111. Specifically, one of the two electrodes of the capacitor C71 is connected to the switch S73 and the output terminal 111, and the other of the two electrodes of the capacitor C71 is connected to ground.

The pre-regulator circuit 10 includes the section from the input terminal 110 to the output terminal 111. The following sections can be also considered to be part of the pre-regulator circuit 10: a section that can be considered to be at the same potential as the input terminal 110 with no switch interposed therebetween; and a section that can be considered to be at the same potential as the output terminal 111 with no switch interposed therebetween. For example, since the input terminal 110 can be considered to be at the same potential as an input terminal 41 of the selector switch circuit 40, the pre-regulator circuit 10 may include the input terminal 41 of the selector switch circuit 40. The same applies to the input terminal 42 of the selector switch circuit 40. In contrast, output terminals 43 to 48 of the selector switch circuit 40 are connected to the input terminal 110 and the output terminal 111 of the pre-regulator circuit 10 with switches interposed therebetween. When the switches are in the connected state (ON), the output terminals 43 to 48 are at the same potential as the input terminal 110 or the output terminal 111. However, when the switches are in the disconnected state (OFF), the output terminals 43 to 48 may be at a potential that is not the same as that of the input terminal 110 or the output terminal 111. Therefore, the pre-regulator circuit 10 includes neither the output terminals 43 to 48, nor the switches connected between: the output terminals 43 to 48; and the input terminals 41 and 42.

The configuration of the pre-regulator circuit 10 in FIG. 3 is illustrative and not intended to be limiting. For example, part of the switches S71 to S74 may be replaced with a diode. The tracker circuit 1 may be configured to not include part or all of the pre-regulator circuit 10.

### 1.2.2 Circuit Configuration of Selector Switch Circuit 40

The circuit configuration of the selector switch circuit 40 will now be described with reference to FIG. 3.

As illustrated in FIG. 3, the selector switch circuit 40 includes the input terminals 41 and 42, and the output terminals 43 to 48.

The input terminal 41 is an example of a second input terminal and connected to the input terminal 110 of the pre-regulator circuit 10. Specifically, the input terminal 41 is connected outside the selector switch circuit 40 to the input terminal 110 of the pre-regulator circuit 10 and to the DC power source 50 and receives the input voltage (Vin) from the DC power source 50. The input terminal 41 is configured to be selectively connectable, inside the selector switch circuit 40, to one of the output terminals 43 to 48.

The input terminal 42 is an example of a third input terminal and connected to the output terminal 111 of the pre-regulator circuit 10. Specifically, the input terminal 42 is connected outside the selector switch circuit 40 to the output terminal 111 of the pre-regulator circuit 10 and receives the regulated voltage (Vpr) from the output terminal 111. The input terminal 42 is configured to be selectively connectable, inside the selector switch circuit 40, to one of the output terminals 43 to 48.

The output terminals 43 to 48 are each an example of a second output terminal. The output terminals 43 to 48 are each configured to be selectively connectable, inside the selector switch circuit 40, to one of the input terminals 41 and 42.

The output terminal 43 is connected outside the selector switch circuit 40 to an input terminal 121 of the switched-capacitor circuit 20. The output terminal 44 is connected outside the selector switch circuit 40 to an input terminal 122 of the switched-capacitor circuit 20. The output terminal 45 is connected outside the selector switch circuit 40 to an input terminal 123 of the switched-capacitor circuit 20. The output terminal 46 is connected outside the selector switch circuit 40 to an input terminal 124 of the switched-capacitor circuit 20. The output terminal 47 is connected outside the selector switch circuit 40 to an input terminal 125 of the switched-capacitor circuit 20. The output terminal 48 is connected outside the selector switch circuit 40 to an input terminal 126 of the switched-capacitor circuit 20.

The selector switch circuit 40 is a multi-connection switch circuit. Specifically, the selector switch circuit 40 is configured to allow each of the input terminals 41 and 42 to connect to a corresponding one of two output terminals selected from among the output terminals 43 to 48. For example, switches that are switchable between connected (ON) and disconnected (OFF) states are arranged in series, one on each path connecting the input terminal 41 to a corresponding one of the output terminals 43 to 48. Switches that are switchable between connected (ON) and disconnected (OFF) states are arranged in series, one on each path connecting the input terminal 42 to a corresponding one of the output terminals 43 to 48. The switches are switchable between ON and OFF under control from the digital control circuit 60. The switching of the switches between ON and OFF enables the output terminals to which the input terminals 41 and 42 are to be respectively connected to be changed.

In the selector switch circuit 40, the input terminals 41 and 42 are not simultaneously connected to the same output terminal. For example, during a period in which the input terminal 41 is connected to the output terminal 43, the input terminal 42 is not connected to the output terminal 43 but is connected to one of the output terminals 44 to 48 other than the output terminal 43. The input terminal 41 is not simultaneously connected to two or more output terminals. For example, during a period in which the input terminal 41 is connected to the output terminal 43, the input terminal 41 is connected to none of the output terminals 44 to 48 other than the output terminal 43. The same applies to the input terminal 42. That is, the input terminal 42 is not simultaneously connected to two or more output terminals. For example, during a period in which the input terminal 42 is connected to the output terminal 48, the input terminal 42 is connected to none of the output terminals 43 to 47 other than the output terminal 48.

The configuration of the selector switch circuit 40 in FIG. 3 is illustrative and not intended to be limiting. The selector switch circuit 40 may be configured and controlled in any manner that allows for selective connection of each of the input terminals 41 and 42 to a corresponding one of two of the output terminals 43 to 48.

### 1.2.3 Circuit Configuration of Switched-Capacitor Circuit 20

The circuit configuration of the switched-capacitor circuit 20 will now be described with reference to FIG. 3. The switched-capacitor circuit 20 has a differential circuit configuration. The switched-capacitor circuit 20 includes the following components: capacitors C20, C30, C40, C50, C60, C11 to C14, and C21 to C24; switches S11 to S14, S21 to S24, S31 to S34, S41 to S44, and S51 to S54; the input terminals 121 to 126; and output terminals 131 to 136. Energy and charge are input from the selector switch circuit 40 to two of nodes N1 to N6 via two of the input terminals 121 to 126, and drawn from the nodes N1, N2, N3, N4, N5, and N6 to the supply modulator 30 via the output terminals 131 to 136.

Each of the input terminals 121 to 126 is an example of a first input terminal configured to receive the input voltage (Vin) and the regulated voltage (Vpr). Specifically, each of the input terminals 121 to 126 is a terminal for receiving, via the selector switch circuit 40, the input voltage (Vin) for input to the tracker circuit 1, and the regulated voltage (Vpr) provided from the pre-regulator circuit 10. The input terminals 121 to 126 are connected one-to-one to the output terminals 43 to 48 of the selector switch circuit 40. The input terminals 121 to 126 are connected one-to-one to the output terminals 131 to 136.

Specifically, the input terminal 121 is connected outside the switched-capacitor circuit 20 to the output terminal 43 of the selector switch circuit 40 and connected inside the switched-capacitor circuit 20 to the node N6. The input terminal 122 is connected outside the switched-capacitor circuit 20 to the output terminal 44 of the selector switch circuit 40 and connected inside the switched-capacitor circuit 20 to the node N5. The input terminal 123 is connected outside the switched-capacitor circuit 20 to the output terminal 45 of the selector switch circuit 40 and connected inside the switched-capacitor circuit 20 to the node N4. The input terminal 124 is connected outside the switched-capacitor circuit 20 to the output terminal 46 of the selector switch circuit 40 and connected inside the switched-capacitor circuit 20 to the node N3. The input terminal 125 is connected outside the switched-capacitor circuit 20 to the output terminal 47 of the selector switch circuit 40 and connected inside the switched-capacitor circuit 20 to the node N2. The input terminal 126 is connected outside the switched-capacitor circuit 20 to the output terminal 48 of the selector switch circuit 40 and connected inside the switched-capacitor circuit 20 to the node N1. As described above, the input terminals 121 to 126 correspond (connect) one-to-one to the nodes N6 to N1.

The output terminal 131 is an example of a third output terminal that outputs one of the discrete voltages. Specifically, the output terminal 131 is a terminal for supplying an output voltage (V6) to the supply modulator 30. The output terminal 131 is connected outside the switched-capacitor circuit 20 to the supply modulator 30 and connected inside the switched-capacitor circuit 20 to the node N6. The output terminal 131 may be integrated with the input terminal 121.

The output terminal 132 is an example of a third output terminal that outputs one of the discrete voltages. Specifically, the output terminal 132 is a terminal for supplying an output voltage (V5) to the supply modulator 30. The output terminal 132 is connected outside the switched-capacitor circuit 20 to the supply modulator 30 and connected inside the switched-capacitor circuit 20 to the node N5. The output terminal 132 may be integrated with the input terminal 122.

The output terminal 133 is an example of a third output terminal that outputs one of the discrete voltages. Specifically, the output terminal 133 is a terminal for supplying an output voltage (V4) to the supply modulator 30. The output terminal 133 is connected outside the switched-capacitor circuit 20 to the supply modulator 30 and connected inside the switched-capacitor circuit 20 to the node N4. The output terminal 133 may be integrated with the input terminal 123.

The output terminal 134 is an example of a third output terminal that outputs one of the discrete voltages. Specifically, the output terminal 134 is a terminal for supplying an output voltage (V3) to the supply modulator 30. The output terminal 134 is connected outside the switched-capacitor circuit 20 to the supply modulator 30 and connected inside the switched-capacitor circuit 20 to the node N3. The output terminal 134 may be integrated with the input terminal 124.

The output terminal 135 is an example of a third output terminal that outputs one of the discrete voltages. Specifically, the output terminal 135 is a terminal for supplying an output voltage (V2) to the supply modulator 30. The output terminal 135 is connected outside the switched-capacitor circuit 20 to the supply modulator 30 and connected inside the switched-capacitor circuit 20 to the node N2. The output terminal 135 may be integrated with the input terminal 125.

The output terminal 136 is an example of a third output terminal that outputs one of the discrete voltages. Specifically, the output terminal 136 is a terminal for supplying an output voltage (V1) to the supply modulator 30. The output terminal 136 is connected outside the switched-capacitor circuit 20 to the supply modulator 30 and connected inside the switched-capacitor circuit 20 to the node N1. The output terminal 136 may be integrated with the input terminal 126.

The discrete voltages are voltages generated based on the input voltage (Vin) and the regulated voltage (Vpr). Specifically, the discrete voltages are generated based on the difference between the input voltage (Vin) and the regulated voltage (Vpr). According to Embodiment 1, the discrete voltages include six output voltages (V1) to (V6). The output voltages (V1) to (V6) are in increasing order of magnitude. That is, the output voltage (V1) is the lowest, and the output voltage (V6) is the highest. The output voltages (V1) to (V6) are voltages at equal intervals. That is, the difference (V2−V1) between the output voltage (V2) and the output voltage (V1) is equal to the difference (V6−V5) between the output voltage (V6) and the output voltage (V5).

According to Embodiment 1, two of the output voltages (V6) to (V1) are each equal to a corresponding one of the input voltage (Vin) or the regulated voltage (Vpr). Specifically, an output voltage equal to the input voltage (Vin) is the output voltage from an output terminal that is connected to the input terminal 41 of the selector switch circuit 40 via one of the output terminals 43 to 48 of the selector switch circuit 40 and via one of the input terminals 121 to 126 of the switched-capacitor circuit 20. Further, an output voltage equal to the regulated voltage (Vpr) is the output voltage from an output terminal that is connected to the input terminal 42 of the selector switch circuit 40 via one of the output terminals 43 to 48 of the selector switch circuit 40 and via one of the input terminals 121 to 126 of the switched-capacitor circuit 20.

The capacitors C11 to C14 and C21 to C24 are flying capacitors (sometimes also referred to as “transfer capacitors”) and can be configured to step up and/or step down the input voltage (Vin) and the regulated voltage (Vpr) that are supplied from the selector switch circuit 40. More specifically, the capacitors C11 to C14 and C21 to C24 transfer charge between: the capacitors C11 to C14 and C21 to C24; and the six nodes N6 to N1 so that at the nodes N6 to N1, voltages V6 to V1 that satisfy (V6−V5):(V5−V4):(V4−V3):(V3−V2):(V2−V1)=1:1:1:1:1 and V6>V5>V4>V3>V2>V1 are maintained.

One of the two electrodes of the capacitor C11 is connected to one terminal of the switch S11 and one terminal of the switch S12. The other of the two electrodes of the capacitor C11 is connected to one terminal of the switch S21 and one terminal of the switch S22.

One of the two electrodes of the capacitor C12 is connected to the one terminal of the switch S21 and the one terminal of the switch S22. The other of the two electrodes of the capacitor C12 is connected to one terminal of the switch S31 and one terminal of the switch S32.

One of the two electrodes of the capacitor C13 is connected to the one terminal of the switch S31 and the one terminal of the switch S32. The other of the two electrodes of the capacitor C13 is connected to one terminal of the switch S41 and one terminal of the switch S42.

One of the two electrodes of the capacitor C14 is connected to the one terminal of the switch S41 and the one terminal of the switch S42. The other of the two electrodes of the capacitor C14 is connected to one terminal of the switch S51 and one terminal of the switch S52.

One of the two electrodes of the capacitor C21 is connected to one terminal of the switch S13 and one terminal of the switch S14. The other of the two electrodes of the capacitor C21 is connected to one terminal of the switch S23 and one terminal of the switch S24.

One of the two electrodes of the capacitor C22 is connected to the one terminal of the switch S23 and the one terminal of the switch S24. The other of the two electrodes of the capacitor C22 is connected to one terminal of the switch S33 and one terminal of the switch S34.

One of the two electrodes of the capacitor C23 is connected to the one terminal of the switch S33 and the one terminal of the switch S34. The other of the two electrodes of the capacitor C23 is connected to one terminal of the switch S43 and one terminal of the switch S44.

One of the two electrodes of the capacitor C24 is connected to the one terminal of the switch S43 and the one terminal of the switch S44. The other of the two electrodes of the capacitor C24 is connected to one terminal of the switch S53 and one terminal of the switch S54.

The capacitors C11 to C14 and the capacitors C21 to C24 are configured to be charged and discharged in a complementary manner as a first phase and a second phase are repeated.

Specifically, in the first phase, the switches S12, S13, S22, S23, S32, S33, S42, S43, S52, and S53 are closed, and the switches S11, S14, S21, S24, S31, S34, S41, S44, S51, and S54 are opened. As a result, for example, the one of the two electrodes of the capacitor C11 is connected to the node N6, the other of the two electrodes of the capacitor C11 and the one of the two electrodes of the capacitor C21 are connected to the node N5, and the other of the two electrodes of the capacitor C21 is connected to the node N4. The one of the two electrodes of the capacitor C12 is connected to the node N5, the other of the two electrodes of the capacitor C12 and the one of the two electrodes of the capacitor C22 are connected to the node N4, and the other of the two electrodes of the capacitor C22 is connected to the node N3. The one of the two electrodes of the capacitor C13 is connected to the node N4, the other of the two electrodes of the capacitor C13 and the one of the two electrodes of the capacitor C23 are connected to the node N3, and the other of the two electrodes of the capacitor C23 is connected to the node N2. The one of the two electrodes of the capacitor C14 is connected to the node N3, the other of the two electrodes of the capacitor C14 and the one of the two electrodes of the capacitor C24 are connected to the node N2, and the other of the two electrodes of the capacitor C24 is connected to the node N1.

In the second phase, the switches S12, S13, S22, S23, S32, S33, S42, S43, S52, and S53 are opened, and the switches S11, S14, S21, S24, S31, S34, S41, S44, S51, and S54 are closed. As a result, the one of the two electrodes of the capacitor C21 is connected to the node N6, the other of the two electrodes of the capacitor C21 and the one of the two electrodes of the capacitor C11 are connected to the node N5, and the other of the two electrodes of the capacitor C11 is connected to the node N4. The one of the two electrodes of the capacitor C22 is connected to the node N5, the other of the two electrodes of the capacitor C22 and the one of the two electrodes of the capacitor C12 are connected to the node N4, and the other of the two electrodes of the capacitor C12 is connected to the node N3. The one of the two electrodes of the capacitor C23 is connected to the node N4, the other of the two electrodes of the capacitor C23 and the one of the two electrodes of the capacitor C13 are connected to the node N3, and the other of the two electrodes of the capacitor C13 is connected to the node N2. The one of the two electrodes of the capacitor C24 is connected to the node N3, the other of the two electrodes of the capacitor C24 and the one of the two electrodes of the capacitor C14 are connected to the node N2, and the other of the two electrodes of the capacitor C14 is connected to the node N1.

The first phase and the second phase are repeated as described above. Consequently, for example, when one of the capacitors C11 and C21 is being charged from the node N6, the other of the capacitors C11 and C21 can be discharged into the capacitor C50. That is, the capacitors C11 and C21 configured to be charged and discharged in a complementary manner. Likewise, the capacitors C12 and C22 configured to be charged and discharged in a complementary manner, the capacitors C13 and C23 are configured to be charged and discharged in a complementary manner, and the capacitors C14 and C24 are configured to be charged and discharged in a complementary manner.

The capacitors C20 to C60 are configured as smoothing capacitors that hold and smooth the output voltages (V1 to V6) at the nodes N1 to N6.

The capacitor C20 is connected between the nodes N2 and N1. Specifically, one of the two electrodes of the capacitor C20 is connected to the node N2. The other of the two electrodes of the capacitor C20 is connected to the node N1.

The capacitor C30 is connected between the nodes N3 and N2. Specifically, one of the two electrodes of the capacitor C30 is connected to the node N3. The other of the two electrodes of the capacitor C30 is connected to the node N2.

The capacitor C40 is connected between the nodes N4 and N3. Specifically, one of the two electrodes of the capacitor C40 is connected to the node N4. The other of the two electrodes of the capacitor C40 is connected to the node N3.

The capacitor C50 is connected between the nodes N5 and N4. Specifically, one of the two electrodes of the capacitor C50 is connected to the node N5. The other of the two electrodes of the capacitor C50 is connected to the node N4.

The capacitor C60 is connected between the nodes N6 and N5. Specifically, one of the two electrodes of the capacitor C60 is connected to the node N6. The other of the two electrodes of the capacitor C60 is connected to the node N5.

The switch S11 is connected between the capacitor C11 and the node N5. Specifically, the one terminal of the switch S11 is connected to the one of the two electrodes of the capacitor C11. The other terminal of the switch S11 is connected to the node N5.

The switch S12 is connected between the capacitor C11 and the node N6. Specifically, the one terminal of the switch S12 is connected to the one of the two electrodes of the capacitor C11. The other terminal of the switch S12 is connected to the node N6.

The switch S21 is connected between the capacitor C11 and the node N4. Further, the switch S21 is connected between the capacitor C12 and the node N4. Specifically, the one terminal of the switch S21 is connected to the other of the two electrodes of the capacitor C11 and the one of the two electrodes of the capacitor C12. The other terminal of the switch S21 is connected to the node N4.

The switch S22 is connected between the capacitor C11 and the node N5. Further, the switch S22 is connected between the capacitor C12 and the node N5. Specifically, the one terminal of the switch S22 is connected to the other of the two electrodes of the capacitor C11 and the one of the two electrodes of the capacitor C12. The other terminal of the switch S22 is connected to the node N5.

The switch S31 is connected between the capacitor C12 and the node N3. Further, the switch S31 is connected between the capacitor C13 and the node N3. Specifically, the one terminal of the switch S31 is connected to the other of the two electrodes of the capacitor C12 and the one of the two electrodes of the capacitor C13. The other terminal of the switch S31 is connected to the node N3.

The switch S32 is connected between the capacitor C12 and the node N4. Further, the switch S32 is connected between the capacitor C13 and the node N4. Specifically, the one terminal of the switch S32 is connected to the other of the two electrodes of the capacitor C12 and the one of the two electrodes of the capacitor C13. The other terminal of the switch S32 is connected to the node N4.

The switch S41 is connected between the capacitor C13 and the node N2. Further, the switch S41 is connected between the capacitor C14 and the node N2. Specifically, the one terminal of the switch S41 is connected to the other of the two electrodes of the capacitor C13 and the one of the two electrodes of the capacitor C14. The other terminal of the switch S41 is connected to the node N2.

The switch S42 is connected between the capacitor C13 and the node N3. Further, the switch S42 is connected between the capacitor C14 and the node N3. Specifically, the one terminal of the switch S42 is connected to the other of the two electrodes of the capacitor C13 and the one of the two electrodes of the capacitor C14. The other terminal of the switch S42 is connected to the node N3.

The switch S51 is connected between the capacitor C14 and the node N1. Further, the switch S51 is connected between the capacitor C15 and the node N1. Specifically, the one terminal of the switch S51 is connected to the other of the two electrodes of the capacitor C14 and the one of the two electrodes of the capacitor C15. The other terminal of the switch S51 is connected to the node N1.

The switch S52 is connected between the capacitor C14 and the node N2. Further, the switch S52 is connected between the capacitor C15 and the node N2. Specifically, the one terminal of the switch S52 is connected to the other of the two electrodes of the capacitor C14 and the one of the two electrodes of the capacitor C15. The other terminal of the switch S52 is connected to the node N2.

The switch S13 is connected between the capacitor C21 and the node N5. Specifically, the one terminal of the switch S13 is connected to the one of the two electrodes of the capacitor C21. The other terminal of the switch S13 is connected to the node N5. That is, the other terminal of the switch S13 is connected to the other terminal of the switch S11 and the other terminal of the switch S22.

The switch S14 is connected between the capacitor C14 and the node N6. Specifically, the one terminal of the switch S14 is connected to the one of the two electrodes of the capacitor C21. The other terminal of the switch S14 is connected to the node N6. That is, the other terminal of the switch S14 is connected to the other terminal of the switch S12.

The switch S23 is connected between the capacitor C21 and the node N4. Further, the switch S23 is connected between the capacitor C22 and the node N4. Specifically, the one terminal of the switch S23 is connected to the other of the two electrodes of the capacitor C21 and the one of the two electrodes of the capacitor C22. The other terminal of the switch S23 is connected to the node N4. That is, the other terminal of the switch S23 is connected to the other terminal of the switch S21 and the other terminal of the switch S32.

The switch S24 is connected between the capacitor C21 and the node N5. Further, the switch S24 is connected between the capacitor C22 and the node N5. Specifically, the one terminal of the switch S24 is connected to the other of the two electrodes of the capacitor C21 and the one of the two electrodes of the capacitor C22. The other terminal of the switch S24 is connected to the node N5. That is, the other terminal of the switch S24 is connected to the other terminal of the switch S11, the other terminal of the switch S22, and the other terminal of the switch S13.

The switch S33 is connected between the capacitor C22 and the node N3. Further, the switch S33 is connected between the capacitor C23 and the node N3. Specifically, the one terminal of the switch S33 is connected to the other of the two electrodes of the capacitor C22 and the one of the two electrodes of the capacitor C23. The other terminal of the switch S33 is connected to the node N3. That is, the other terminal of the switch S33 is connected to the other terminal of the switch S31 and the other terminal of the switch S42.

The switch S34 is connected between the capacitor C22 and the node N4. Further, the switch S34 is connected between the capacitor C23 and the node N4. Specifically, the one terminal of the switch S34 is connected to the other of the two electrodes of the capacitor C22 and the one of the two electrodes of the capacitor C23. The other terminal of the switch S34 is connected to the node N4. That is, the other terminal of the switch S34 is connected to the other terminal of the switch S21, the other terminal of the switch S32, and the other terminal of the switch S23.

The switch S43 is connected between the capacitor C23 and the node N2. Further, the switch S43 is connected between the capacitor C24 and the node N2. Specifically, the one terminal of the switch S43 is connected to the other of the two electrodes of the capacitor C23 and the one of the two electrodes of the capacitor C24. The other terminal of the switch S43 is connected to the node N2. That is, the other terminal of the switch S43 is connected to the other terminal of the switch S41 and the other terminal of the switch S52.

The switch S44 is connected between the capacitor C23 and the node N3. Further, the switch S44 is connected between the capacitor C24 and the node N3. Specifically, the one terminal of the switch S44 is connected to the other of the two electrodes of the capacitor C23 and the one of the two electrodes of the capacitor C24. The other terminal of the switch S44 is connected to the node N3. That is, the other terminal of the switch S44 is connected to the other terminal of the switch S31, the other terminal of the switch S42, and the other terminal of the switch S33.

The switch S53 is connected between the capacitor C24 and the node N1. Further, the switch S53 is connected between the capacitor C25 and the node N1. Specifically, the one terminal of the switch S53 is connected to the other of the two electrodes of the capacitor C24 and the one of the two electrodes of the capacitor C25. The other terminal of the switch S53 is connected to the node N1. That is, the other terminal of the switch S53 is connected to the other terminal of the switch S51.

The switch S54 is connected between the capacitor C24 and the node N2. Further, the switch S54 is connected between the capacitor C25 and the node N2. Specifically, the one terminal of the switch S54 is connected to the other of the two electrodes of the capacitor C24 and the one of the two electrodes of the capacitor C25. The other terminal of the switch S54 is connected to the node N2. That is, the other terminal of the switch S54 is connected to the other terminal of the switch S41, the other terminal of the switch S52, and the other terminal of the switch S43.

A first set of switches including the switches S12, S13, S22, S23, S32, S33, S42, S43, S52, and S53, and a second set of switches including the switches S11, S14, S21, S24, S31, S34, S41, S44, S51, and S54 are switched between ON and OFF in a complementary manner based on a control signal from the digital control circuit 60. Specifically, in the first phase, the first set of switches is closed, and the second set of switches is opened. Conversely, in the second phase, the first set of switches is opened, and the second set of switches is closed.

For example, in one of the first phrase or the second phase, charging of the capacitors C20 to C60 from the capacitors C11 to C14 is executed, and in the other of the first phase or the second phase, charging of the capacitors C20 to C60 from the capacitors C21 to C24 is executed. That is, the capacitors C20 to C60 are constantly charged from the capacitors C11 to C14 or the capacitors C21 to C24. This ensures that even when current flows rapidly from the nodes N1 to N6 to the supply modulator 30, the nodes N1 to N6 are rapidly replenished with charge. This configuration in turn reduces fluctuations in potential at the nodes N1 to N6.

The operation mentioned above allows a substantially equal voltage to be maintained across each of the capacitors C20 to C60 in the switched-capacitor circuit 20. Specifically, the voltages V6 to V1 that satisfy (V6−V5):(V5−V4):(V4−V3):(V3−V2):(V2−V1)=1:1:1:1:1 are maintained at the six nodes N6 to N1.

It is noted that the ratio (V6−V5):(V5−V4):(V4−V3):(V3−V2):(V2−V1) is not limited to 1:1:1:1:1 and can be designed to any value as would be appreciated to one skilled in the art.

The switched-capacitor circuit 20 includes the following sections: a section including the flying capacitors (e.g., the capacitor C11), the smoothing capacitors (e.g., the capacitor C20), and the first and second sets of switches (e.g., the switch S11); and a section that can be considered to be at the same potential as each of the input terminals 121 to 126 and the output terminals 131 to 136 with no switch interposed therebetween.

For example, since the input terminal 121 can be considered to be at the same potential as the output terminal 43 of the selector switch circuit 40, the switched-capacitor circuit 20 may include the output terminal 43. The same applies to the output terminals 44 to 48 of the selector switch circuit 40. In contrast, the input terminals 41 and 42 of the selector switch circuit 40 are connected to the input terminals 121 to 126 of the switched-capacitor circuit 20 with switches interposed therebetween. Consequently, when the switches are in the connected state (ON), the input terminals 41 and 42 are at the same potential as one of the input terminals 121 to 126, whereas when the switches are in the disconnected state (OFF), the input terminals 41 and 42 can be at a potential that is not the same as the potential of one of the input terminals 121 to 126. Therefore, the switched-capacitor circuit 20 includes neither the input terminals 41 and 42, nor the switches connected between: the input terminals 41 and 42; and the output terminals 43 to 48.

Likewise, since the output terminal 131 can be considered to be at the same potential as an input terminal 141 of the supply modulator 30, the switched-capacitor circuit 20 may include the input terminal 141. The same applies to input terminals 142 to 146 of the supply modulator 30. In contrast, an output terminal 147 of the supply modulator 30 is connected to the output terminals 131 to 136 of the switched-capacitor circuit 20 with switches S81 to S86 interposed therebetween. Consequently, when the switches S81 to S86 are in the connected state (ON), the output terminal 147 is at the same potential as one of the output terminals 131 to 136, whereas when the switches S81 to S86 are in the disconnected state (OFF), the output terminal 147 may be at a potential that is not the same as the potential of one of the output terminals 131 to 136. Therefore, the switched-capacitor circuit 20 includes neither the output terminal 147 nor the switches S81 to S86.

### 1.2.4 Circuit Configuration of Supply Modulator 30

The circuit configuration of the supply modulator 30 will now be described with reference to FIG. 3. The supply modulator 30 includes the input terminals 141 to 146, the switches S81 to S86, and the output terminal 147.

The input terminals 141 to 146 are an example of a plurality of fifth input terminals to receive the discrete voltages (V1 to V6) generated in the switched-capacitor circuit 20. The input terminals 141 to 146 are respectively connected outside the supply modulator 30 to the output terminals 131 to 136 of the switched-capacitor circuit 20, and respectively connected inside the supply modulator 30 to the switches S81 to S86.

The output terminal 147 is an example of a fourth output terminal to selectively supply the power amplifier 2 with at least one voltage selected from the group consisting of the input voltage and the discrete voltages. The output terminal 147 is connected outside the supply modulator 30 to the power amplifier 2 and connected inside the supply modulator 30 to the switches S81 to S86.

The switch S81 is connected between the input terminal 141 and the output terminal 147. With the connection configuration mentioned above, the switch S81 is switched between open and closed states by a control signal provided from the digital control circuit 60 to allow switching between connection and disconnection between the input terminal 141 and the output terminal 147.

The switch S82 is connected between the input terminal 142 and the output terminal 147. With the connection configuration mentioned above, the switch S82 is switched between open and closed states by a control signal provided from the digital control circuit 60 to allow switching between connection and disconnection between the input terminal 142 and the output terminal 147.

The switch S83 is connected between the input terminal 143 and the output terminal 147. With the connection configuration mentioned above, the switch S83 is switched between open and closed states by a control signal provided from the digital control circuit 60 to allow switching between connection and disconnection between the input terminal 143 and the output terminal 147.

The switch S84 is connected between the input terminal 144 and the output terminal 147. With the connection configuration mentioned above, the switch S84 is switched between open and closed states by a control signal provided from the digital control circuit 60 to allow switching between connection and disconnection between the input terminal 144 and the output terminal 147.

The switch S85 is connected between the input terminal 145 and the output terminal 147. With the connection configuration mentioned above, the switch S85 is switched between open and closed states by a control signal provided from the digital control circuit 60 to allow switching between connection and disconnection between the input terminal 145 and the output terminal 147.

The switch S86 is connected between the input terminal 146 and the output terminal 147. With the connection configuration mentioned above, the switch S86 is switched between open and closed states by a control signal provided from the digital control circuit 60 to allow switching between connection and disconnection between the input terminal 146 and the output terminal 147.

According to Embodiment 1, the switches S81 to S86 are controlled to be exclusively ON. That is, the switches S81 to S86 are controlled such that only one of the switches S81 to S86 is closed, with all of the remaining switches S81 to S86 being opened. This configuration enables the supply modulator 30 to supply the power amplifier 2 with one voltage selected from among the discrete voltages (V1 to V6).

The configuration of the supply modulator 30 in FIG. 3 is illustrative and not intended to be limiting. In particular, the switches S81 to S86 may be configured and controlled in any manner that allows at least one of the six input terminals 141 to 146 to be selectively connected to the output terminal 147. For example, four of the switches S81 to S86 may be closed, and the remaining two of the switches S81 to S86 may be opened.

### 1.2.5 Circuit Configuration of Digital Control Circuit 60

The circuit configuration of the digital control circuit 60 will now be described with reference to FIG. 3. The digital control circuit 60 includes a first controller 61, and a second controller 62.

The first controller 61 is configured to generate a control signal for controlling the switched-capacitor circuit 20, by processing a serial data signal supplied from the RFIC 5 via a control terminal (not illustrated). An example of the serial data signal to be used is a source-synchronous digital control signal. The opening and closing of the switches S11 to S14, S21 to S24, S31 to S34, S41 to S44, and S51 to S54 included in the switched-capacitor circuit 20 is controlled by the control signal provided from the first controller 61.

The first controller 61 is configured to generate a control signal for controlling the pre-regulator circuit 10, by processing a serial data signal supplied from the RFIC 5 via a control terminal (not illustrated). The opening and closing of the switches S71 to S74 included in the pre-regulator circuit 10 is controlled by the control signal provided from the first controller 61. The pre-regulator circuit 10 is thus configured to regulate, in accordance with the serial data signal, the magnitude of the regulated voltage (Vpr) to be generated and output by the pre-regulator circuit 10.

The first controller 61 is configured to generate a control signal for controlling the selector switch circuit 40, by processing a serial data signal supplied from the RFIC 5 via a control terminal (not illustrated). The selector switch circuit 40 is thus configured to select two of the input terminals 121 to 126 of the switched-capacitor circuit 20 in accordance with the serial data signal. Specifically, the selector switch circuit 40 is configured to select two of the input terminals 121 to 126 of the switched-capacitor circuit 20 in accordance with the serial data signal by selecting, from the output terminals 43 to 48, output terminals to which the input terminals 41 and 42 are to be respectively connected.

As a serial data signal, a clock-embedded digital control signal may be used. The first controller 61 may generate a control signal for controlling the supply modulator 30.

The second controller 62 generates a control signal for controlling the supply modulator 30, by processing a parallel data signal supplied from the RFIC 5 via a control terminal (not illustrated). As the parallel data signal, for example, digital control logic/line (DCL) signals (DCL1, DCL2, and DCL3) are used. The DCL signals (DCL1, DCL2, and DCL3) are generated by the RFIC 5 based on the envelope signal of a radio frequency signal. The opening and closing of the switches S81 to S86 included in the supply modulator 30 is controlled by the control signal provided from the second controller 62. The supply modulator 30 is thus configured to select at least one of the discrete voltages in accordance with the parallel data signal.

The DCL signals (DCL1, DCL2, and DCL3) are each a 1-bit signal. The levels L1 to L6 of power supply voltage (voltage levels) are each represented by a combination of three 1-bit signals. The levels L1 to L6 correspond to the respective voltage values of the discrete voltages (V1 to V6). For example, L1, L2, L3, L4, L5, and L6 are represented by “000”, “001”, “010”, “011”, “100”, and “101”, respectively. Moreover, a gray code may be used to represent a voltage level according to an exemplary aspect.

According to Embodiment 1, three DCL signals are used in controlling the supply modulator 30. However, the number of DCL signals is not limited to three and be another number of signals as would be appreciated to one skilled in the art. For example, one or any plural number of DCL signals may be used depending on the number of voltage levels selectable by each supply modulator 30. In addition, an example of the parallel data signal to be used for controlling the supply modulator 30 is not limited to DCL signals as would be appreciated to one skilled in the art.

### 1.3 Voltage Supply Method

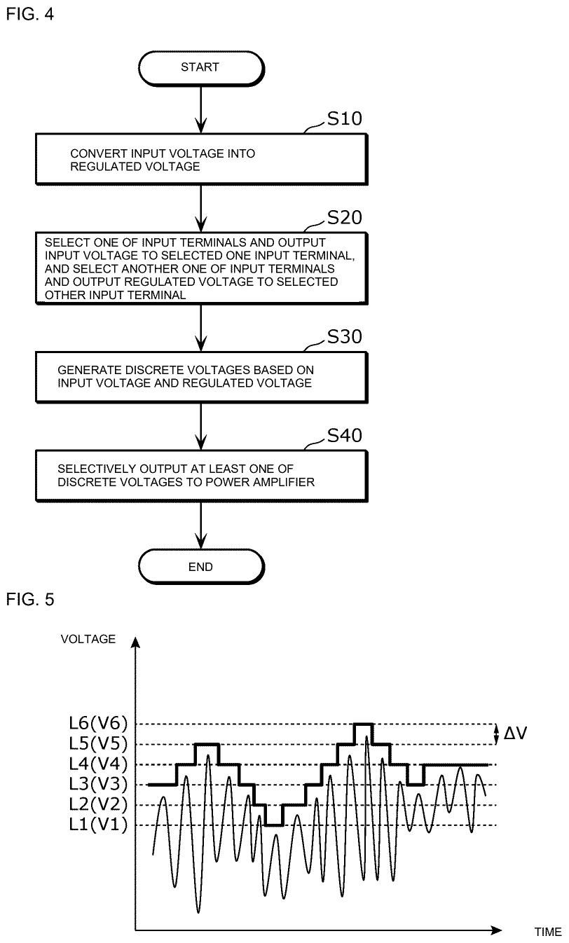

A voltage supply method according to Embodiment 1 will now be described with reference to FIG. 4. FIG. 4 is a flowchart illustrating the voltage supply method according to Embodiment 1.

First, by use of the pre-regulator circuit 10, the input voltage (Vin) is converted into the regulated voltage (Vpr) (S10). Subsequently, by use of the selector switch circuit 40, one input terminal of the input terminals 121 to 126 of the switched-capacitor circuit 20 is selected and the input voltage (Vin) is output to the selected one input terminal, and another input terminal of the input terminals 121 to 126 is selected and the regulated voltage (Vpr) is output to the selected other input terminal (S20).

Subsequently, by use of the switched-capacitor circuit 20, the discrete voltages (V1 to V6) are generated based on the input voltage (Vin) and the regulated voltage (Vpr) (S30).

Lastly, by use of the supply modulator 30, at least one of the discrete voltages (V1 to V6) is selectively supplied to the power amplifier 2 (S40). That is, at least one voltage is selected from the discrete voltages (V1 to V6), and the selected at least one voltage is supplied to the power amplifier 2. As the voltage selection mentioned above is performed based on an envelope signal, the D-ET mode is applied to the power amplifier 2.

### 1.4 Voltages that can be Output by Tracker Circuit 1

Voltages that can be output by the tracker circuit 1 configured as described above will now be described with reference to FIG. 5.

FIG. 5 is a graph illustrating a plurality of levels L1 to L6 of power supply voltages that can be output by the tracker circuit 1 according to Embodiment 1, and the power supply voltage to be supplied to the power amplifier 2. In FIG. 5, the horizontal axis represents time, and the vertical axis represents voltage. A thick solid line represents power supply voltage, and a thin solid line (waveform) represents modulated signal. A plurality of thin dashed lines represents the levels L1 to L6 of voltages that can be output by the tracker circuit 1, more specifically, the discrete voltages (V1 to V6) to be output by the switched-capacitor circuit 20.

In the D-ET mode, as illustrated in FIG. 1C as well, the power supply voltage is modulated based on an envelope signal within one frame, and then output. As illustrated in FIG. 5, the power supply voltage to be supplied to the power amplifier 2 can take the six discrete levels L1 to L6. The levels L1 to L6 respectively correspond to the six discrete voltages (V1 to V6) to be output by the switched-capacitor circuit 20. According to Embodiment 1, the levels L1 to L6 are set such that their respective voltage values increase in this order.

The switched-capacitor circuit 20 is configured to generate and output the discrete voltages (V1 to V6) in accordance with: the magnitude of the input voltage (Vin); the magnitude of the regulated voltage (Vpr); and the combination of two nodes to which the input voltage (Vin) and the regulated voltage (Vpr) are to be respectively input. According to Embodiment 1, the presence of the selector switch circuit 40 enable the combination to be change for two nodes to which the input voltage (Vin) and the regulated voltage (Vpr) are to be respectively input. The magnitude of the regulated voltage (Vpr) is also variable. Further, the input voltage (Vin) may also vary depending on the usage condition, the usage environment, and other factors. For example, the input voltage from the DC power source 50 tends to decrease in magnitude from the initial state with increases in operating time, number of uses, and other factors. As described above, the magnitude of the input voltage (Vin), the magnitude of the regulated voltage (Vpr), and the combination of two nodes to which the input voltage (Vin) and the regulated voltage (Vpr) are to be respectively input are all variable. This configuration makes it possible to change the respective values of the discrete voltages (V1 to V6) to be generated and output by the switched-capacitor circuit 20.

In the tracker circuit 1, the nodes N1 to N6, the input terminals 126 to 121, the output terminals 136 to 131, and the output terminals 48 to 43 of the selector switch circuit 40 respectively correspond one-to-one to the levels L1 to L6. An input of the input voltage (Vin) to a given node indicates that one of the output terminals 43 to 48 that corresponds to the node is connected to the input terminal 41. Likewise, an input of the regulated voltage (Vpr) to a given node indicates that one of the output terminals 43 to 48 that corresponds to the node is connected to the input terminal 42.

Two of the discrete voltages (V1 to V6) are respectively equal to the input voltage (Vin) and the regulated voltage (Vpr). Specifically, among the output terminals 131 to 136 of the switched-capacitor circuit 20, an output terminal connected to the input terminal 41 outputs a voltage equal to the input voltage (Vin). Among the output terminals 131 to 136 of the switched-capacitor circuit 20, an output terminal connected to the input terminal 42 outputs a voltage equal to the regulated voltage (Vpr). The output terminals 131 to 136 may each connect to one of the input terminals 41 and 42 via a corresponding one of the nodes N6 to N1, via a corresponding one of the input terminals 121 to 126, and via a corresponding one of the output terminals 43 to 48 of the selector switch circuit 40.

The six discrete voltages (V1 to V6) to be output by the switched-capacitor circuit 20 are voltages at equal intervals. For example, when the difference between the highest voltage (V6) and the second highest voltage (V5) is ΔV, the following relationship holds: (V6−V5)=(V5−V4)=(V4−V3)=(V3−V2)=(V2−V1)=ΔV. When the number of the capacitors C20 to C60 connected between two nodes to which the input voltage (Vin) and the regulated voltage (Vpr) are to be respectively input is n, the value of ΔV is represented as follows: ΔV=|Vin−Vpr|/n. The value of n corresponds to the difference between the respective levels of the two nodes. For example, when the input voltage (Vin) is input to the node N5 (level L5) and the regulated voltage (Vpr) is input to the node N2 (level L2), n=3.

According to Embodiment 1, the respective values of the discrete voltages (V1 to V6) and the difference ΔV are variable. This configuration enables a large number of voltage levels to be set within a range including power values that occur with higher frequency in the vicinity of the average power of the radio frequency signal (hereinafter referred to as the “high occurrence frequency range”). As a result, a more suitable voltage can be supplied to the power amplifier 2 in accordance with the power of the radio frequency signal. This helps to improve power-added efficiency more effectively.

### 1.5 Example of Operation of Selector Switch Circuit 40 and Pre-Regulator Circuit 10

Specific examples of operation of the selector switch circuit 40 and the pre-regulator circuit 10 will now be described.

### 1.5.1 First Example

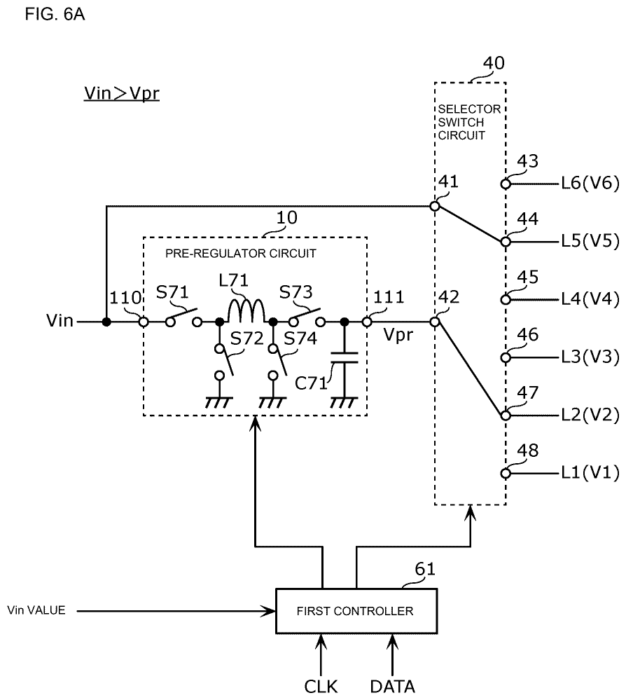

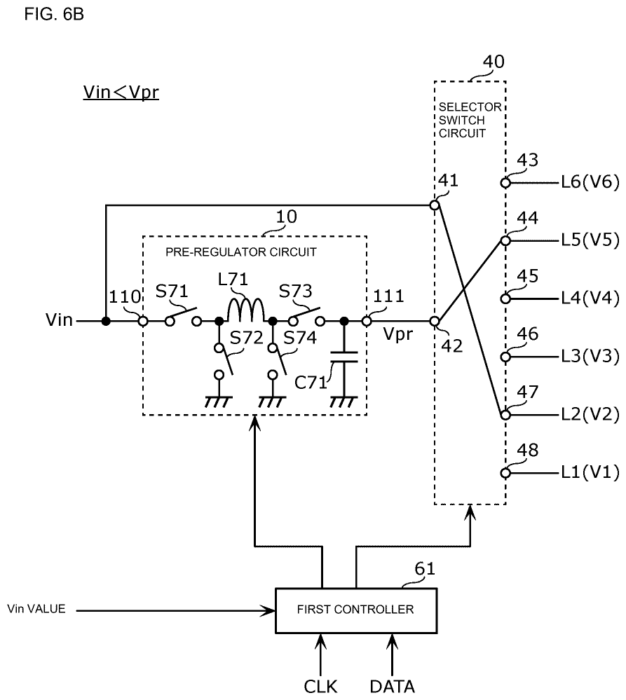

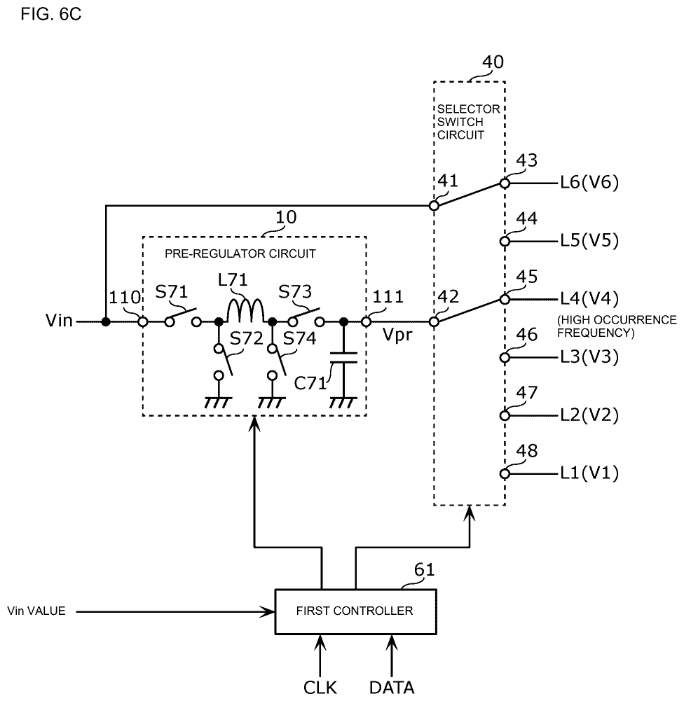

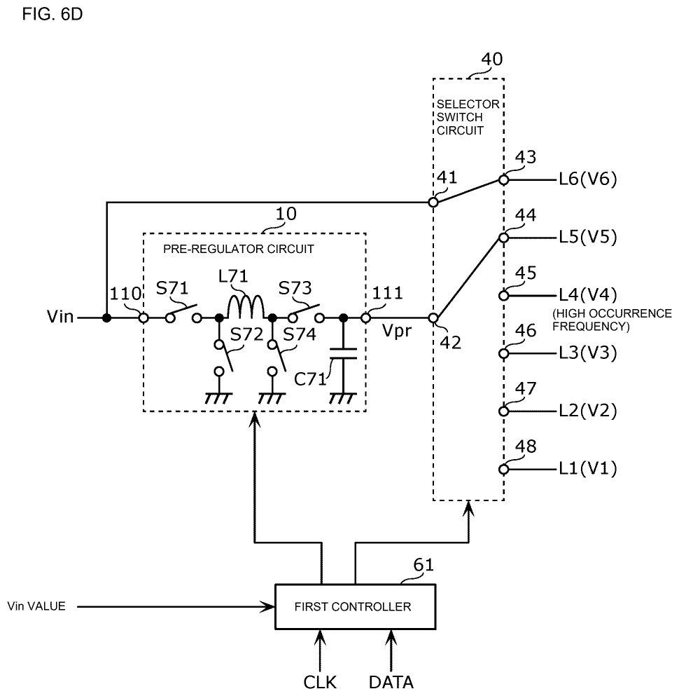

First, a first example of operation of the selector switch circuit 40 and the pre-regulator circuit 10 will be described with reference to FIG. 6A and FIG. 6B.

FIG. 6A and FIG. 6B are circuit diagrams each illustrating a first example of a connection configuration for the selector switch circuit 40 according to Embodiment 1. FIG. 6A and FIG. 6B each illustrate, among the components of the tracker circuit 1 illustrated in FIG. 3, only the pre-regulator circuit 10, the selector switch circuit 40, and the first controller 61 of the digital control circuit 60.

According to the present operation example, the selector switch circuit 40 is configured to select, from among the input terminals 121 to 126 of the switched-capacitor circuit 20, an input terminal to which at least one of the input voltage (Vin) or the regulated voltage (Vpr) is to be output, based on the magnitude of the output voltage from the DC power source 50, that is, based on the magnitude of the input voltage (Vin) for the tracker circuit 1. Specifically, the selector switch circuit 40 is configured to select, from among the input terminals 121 to 126 of the switched-capacitor circuit 20, an input terminal to which at least one of the input voltage (Vin) or the regulated voltage (Vpr) is to be output, based on the difference between the input voltage (Vin) and the regulated voltage (Vpr). More specifically, the selector switch circuit 40 changes the connection configuration for each of the input terminals 41 and 42 with respect to the output terminals 43 to 48, based on the magnitude relationship between the input voltage (Vin) and the regulated voltage (Vpr).

According to the present operation example, the first controller 61 that controls the selector switch circuit 40 acquires a Vin value, which represents the magnitude of the input voltage (Vin). For example, in the path connecting the output terminal of the DC power source 50 and the input terminal of the tracker circuit 1 (the input terminal 110 of the pre-regulator circuit 10), a voltage detector (not illustrated) is provided to detect the magnitude of the input voltage (Vin). The voltage detector outputs the detected magnitude of the input voltage (Vin) to the first controller 61.

The first controller 61 processes a serial data signal supplied from the RFIC 5 via a control terminal (not illustrated) and determines the magnitude of the regulated voltage (Vpr) to be generated and output by the pre-regulator circuit 10. The magnitude of the regulated voltage (Vpr) is, for example, determined based on values such as the average power and the peak power of the radio frequency signal.

The first controller 61 compares the detected magnitude of the input voltage (Vin) with the determined magnitude of the regulated voltage (Vpr). Based on the comparison result, the first controller 61 outputs a control signal to each of the pre-regulator circuit 10 and the selector switch circuit 40.

When the input voltage (Vin) is higher than the determined regulated voltage (Vpr), the pre-regulator circuit 10 performs a step-down operation based on the control signal provided from the first controller 61. Specifically, the pre-regulator circuit 10 converts the input voltage (Vin) into the regulated voltage (Vpr) that is lower than the input voltage (Vin), and outputs the resulting regulated voltage (Vpr) from the output terminal 111.

Further, when the input voltage (Vin) is higher than the determined regulated voltage (Vpr), then based on the control signal from the first controller 61, the selector switch circuit 40 connects the input terminal 41 to one of the output terminals 43 to 48 that has a higher voltage level than an output terminal to which the input terminal 42 is to be connected. For example, as illustrated in FIG. 6A, the input terminal 42 is connected to the output terminal 47 corresponding to the level L2, and the input terminal 41 is connected to the output terminal 44 corresponding to the level L5, which is higher than the level L2.

When the input voltage (Vin) is lower than the determined regulated voltage (Vpr), the pre-regulator circuit 10 performs a step-up operation based on the control signal provided from the first controller 61. Specifically, the pre-regulator circuit 10 converts the input voltage (Vin) into the regulated voltage (Vpr) that is higher than the input voltage (Vin), and outputs the resulting regulated voltage (Vpr) from the output terminal 111.

Further, when the input voltage (Vin) is lower than the determined regulated voltage (Vpr), the selector switch circuit 40 connects the input terminal 41 to one of the output terminals 43 to 48 that has a lower voltage level than an output terminal to which the input terminal 42 is to be connected. For example, as illustrated in FIG. 6B, the input terminal 42 is connected to the output terminal 44 corresponding to the level L5, and the input terminal 41 is connected to the output terminal 47 corresponding to the level L2, which is lower than the level L5.

As described above, according to the present operation example, even when the input voltage (Vin) varies, the pre-regulator circuit 10 is configured to generate and output the regulated voltage (Vpr) having a magnitude that is determined by the first controller 61. For example, the magnitude of the regulated voltage (Vpr) is allowed to remain constant irrespective of the magnitude of the input voltage (Vin).

When the magnitude relationship between the input voltage (Vin) and the regulated voltage (Vpr) changes, the connection configurations for the input terminals 41 and 42 are swapped. This configuration maintains the magnitude relationship among the discrete voltages (V1 to V6) (the magnitude relationship among the levels L1 to L6) to be output from the switched-capacitor circuit 20. This configuration enables the discrete voltages (V1 to V6) to be generated and output in a stable manner irrespective of the variation of the input voltage (Vin).

The above-mentioned changing of operation of the pre-regulator circuit 10, and the above-mentioned changing of a connection configuration for the selector switch circuit 40 are executed, for example, in units of one frame or in larger units. Ensuring that these changing processes are not executed at high speed allows for stable operation of the switched-capacitor circuit 20.

The foregoing description of the present operation example is directed to the case where, when the magnitude relationship between the input voltage (Vin) and the regulated voltage (Vpr) changes, the connection configurations for the input terminals 41 and 42 are swapped between the node N2 and the node N5. This, however, is not intended to be limiting. Alternatively, one of the input terminals 41 and 42 may be connected to a node other than the nodes N2 and N5. For example, when the state Vin>Vpr in FIG. 6A changes to the state Vin<Vpr, the input terminal 41 may remain connected to the output terminal 44 (the node N5), and the input terminal 42 may be connected to the output terminal 43 (the node N6). Alternatively, the input terminal 42 may remain connected to the output terminal 47 (the node N2), and the input terminal 41 may be connected to the output terminal 48 (the node N1). As described above, the output terminal to connect to may be changed only for one of the input terminals 41 and 42. Alternatively, when the state Vin>Vpr in FIG. 6A changes to the state Vin<Vpr, the input terminal 42 may be connected to the output terminal 43 (the node N6), and the input terminal 41 may be connected to the output terminal 48 (the node N1). In this way, the combination of two output terminals (two nodes) to which these input terminals are to be respectively connected may differ before and after the change of connections.

Although the foregoing description of the present operation example is directed to the case where the first controller 61 acquires the Vin value, this is not intended to be limiting. Alternatively, the RFIC 5 may acquire the Vin value, and control operation of each of the pre-regulator circuit 10 and the selector switch circuit 40.

### 1.5.2 Second Example

A second example of operation of the selector switch circuit 40 and the pre-regulator circuit 10 will now be described with reference to FIG. 6C.

FIG. 6C is a circuit diagram illustrating a second example of a connection configuration for the selector switch circuit 40 according to Embodiment 1. FIG. 6C illustrates, among the components of the tracker circuit 1 illustrated in FIG. 3, only the pre-regulator circuit 10, the selector switch circuit 40, and the first controller 61 of the digital control circuit 60.

According to the present operation example, the selector switch circuit 40 changes an output terminal to which the input terminal 42 is to be connected, such that the regulated voltage (Vpr) from the pre-regulator circuit 10 is assigned to a voltage level corresponding to the most frequently occurring power value in the vicinity of the average power of a radio frequency signal. For example, as illustrated in FIG. 6C, when the level L4 corresponds to a power value with high occurrence frequency, the selector switch circuit 40 connects the input terminal 42 to the output terminal 45 (the level L4) based on a control signal provided from the first controller 61.

The pre-regulator circuit 10 is configured to generate and output a stable regulated voltage (Vpr) irrespective of the variation of the input voltage (Vin). Accordingly, by using the regulated voltage (Vpr) for a voltage corresponding to a power value with high occurrence frequency, the power supply voltage supplied to the power amplifier 2 can be easily stabilized. This configuration improves power-added efficiency. Further, the pre-regulator circuit 10 is also configured to optimize the magnitude of the regulated voltage (Vpr) based on a control signal provided from the first controller 61. This configuration further improves power-added efficiency.

The above-mentioned changing of operation of the pre-regulator circuit 10, and the above-mentioned changing of a connection configuration for the selector switch circuit 40 are executed, for example, in units of one frame or in larger units. Ensuring that these changing processes are not executed at high speed allows for stable operation of the switched-capacitor circuit 20.

As with the first example, according to the present operation example as well, the selector switch circuit 40 may, when the input voltage (Vin) varies, change an output terminal to which the input terminal 41 is to be connected. For example, the selector switch circuit 40 may, while maintaining the connection between the input terminal 42 and the output terminal 45 corresponding to a voltage level with high occurrence frequency, connect the input terminal 41 to one of the output terminals 46 to 48 in response to the input voltage (Vin) becoming lower than the regulated voltage (Vpr). This configuration enables the discrete voltages (V1 to V6) to be generated that are stable irrespective of the variation of the input voltage (Vin), and thus further improve power-added efficiency. Alternatively, according to the present operation example, a voltage detector (not illustrated) that detects the magnitude of the input voltage (Vin) may be omitted. That is, the first controller 61 may be configured to not acquire the Vin value representing the detected magnitude of the input voltage (Vin).

### 1.5.3 Third Example

A third second example of operation of the selector switch circuit 40 and the pre-regulator circuit 10 will now be described with reference to FIG. 6D.

FIG. 6D is a circuit diagram illustrating a third example of a connection configuration for the selector switch circuit 40 according to Embodiment 1. FIG. 6D illustrates, among the components of the tracker circuit 1 illustrated in FIG. 3, only the pre-regulator circuit 10, the selector switch circuit 40, and the first controller 61 of the digital control circuit 60.

According to the present operation example, the selector switch circuit 40 changes output terminals to which the input terminals 41 and 42 are to be respectively connected, such that the input voltage (Vin) and the regulated voltage (Vpr) are input to two adjacent nodes. For example, as illustrated in FIG. 6D, based on a control signal from the first controller 61, the selector switch circuit 40 connects the input terminal 41 to the output terminal 43, and connects the input terminal 42 to the output terminal 44.

Consequently, the pre-regulator circuit 10 is configured to generate the regulated voltage (Vpr) whose difference from the input voltage (Vin) is small. This configuration reduces voltage variation in the pre-regulator circuit 10, which, in turn, improves power-added efficiency.

The above-mentioned changing of operation of the pre-regulator circuit 10, and the above-mentioned changing of a connection configuration for the selector switch circuit 40 are executed, for example, in units of one frame or in larger units. Ensuring that these changing processes are not executed at high speed allows for stable operation of the switched-capacitor circuit 20.

As with the second example, according to the present operation example as well, the regulated voltage (Vpr) from the pre-regulator circuit 10 may be assigned to a voltage level corresponding to the most frequently occurring power value in the vicinity of the average power of a radio frequency signal. That is, the selector switch circuit 40 may connect the input terminal 42 to the output terminal 45 and connect the input terminal 41 to the output terminal 44. This configuration improves power-added efficiency.

As with the first example, according to the present operation example as well, the selector switch circuit 40 may, when the input voltage (Vin) varies, change an output terminal to which the input terminal 41 is to be connected. For example, the selector switch circuit 40 may, while maintaining the connection between the input terminal 42 and the output terminal 45 corresponding to a voltage level with high occurrence frequency, connect the input terminal 41 to the output terminal 46 in response to the input voltage (Vin) becoming lower than the regulated voltage (Vpr). This configuration enables the discrete voltages (V1 to V6) to be enabled that are stable irrespective of the variation of the input voltage (Vin), which can contribute to further improvement in power-added efficiency. Alternatively, according to the present operation example, a voltage detector (not illustrated) that detects the magnitude of the input voltage (Vin) may be omitted. That is, the first controller 61 may be configured to not acquire the Vin value representing the detected magnitude of the input voltage (Vin).

### 1.6 Technical Effects

As described above, the tracker circuit 1 according to Embodiment 1 includes the pre-regulator circuit 10, the switched-capacitor circuit 20, the supply modulator 30, and the selector switch circuit 40. The pre-regulator circuit 10 is configured to convert the input voltage (Vin) into the regulated voltage (Vpr). The switched-capacitor circuit 20 includes the input terminals 121 to 126 that receive the input voltage (Vin) and the regulated voltage (Vpr). The switched-capacitor circuit 20 is configured to generate and output the discrete voltages (V1 to V6). The supply modulator 30 is configured to selectively output at least one of the discrete voltages (V1 to V6) to the power amplifier 2. The selector switch circuit 40 is connected to the pre-regulator circuit 10 and the switched-capacitor circuit 20. The selector switch circuit 40 is configured to select one of the input terminals 121 to 126 and output the input voltage (Vin) to the one of the input terminals 121 to 126 and configured to select another one of the input terminals 121 to 126 and output the regulated voltage (Vpr) to the other one of the input terminals 121 to 126.

According to another aspect, the tracker circuit 1 according to Embodiment 1 includes the pre-regulator circuit 10, the selector switch circuit 40, the switched-capacitor circuit 20, and the supply modulator 30. The pre-regulator circuit 10 includes the input terminal 110 that receives the input voltage (Vin), and the output terminal 11I that outputs the regulated voltage (Vpr) generated from the input voltage (Vin). The selector switch circuit 40 includes the input terminal 41 connected to the input terminal 110, the input terminal 42 connected to the output terminal 111, and the output terminals 43 to 48. The switched-capacitor circuit 20 includes the input terminals 121 to 126 connected one-to-one to the output terminals 43 to 48, and the output terminals 131 to 136 that are connected one-to-one to the input terminals 121 to 126 and that output the plurality of discrete voltages (V1 to V6) generated based on the input voltage (Vin) and the regulated voltage (Vpr). The supply modulator 30 includes the input terminals 141 to 146 respectively connected to the output terminals 131 to 136, and the output terminal 147 connected to the power amplifier 2.

According to the above-mentioned configuration, the presence of the selector switch circuit 40 makes it possible to change input terminals (nodes) to which the input voltage (Vin) and the regulated voltage (Vpr) are to be respectively input. For example, when the input voltage (Vin) varies, an input terminal to which at least one of the input voltage (Vin) or the regulated voltage (Vpr) is to be input can be changed. This configuration stabilizes the discrete voltages (V1 to V6) and improves power-added efficiency.

In the tracker circuit 1, the selector switch circuit 40 includes the input terminal 41 that receives the input voltage (Vin), the input terminal 42 that receives the regulated voltage (Vpr), and the input terminals 121 to 126 connected one-to-one to the output terminals 43 to 48. The input terminals 41 and 42 are each configured to be selectively connectable to the output terminals 43 to 48.

The above-mentioned configuration allows for increased flexibility in selecting input terminals to which the input voltage (Vin) and the regulated voltage (Vpr) are to be respectively input. This configuration enables more suitable discrete voltages (V1 to V6) to be generated in accordance with a radio frequency signal, and thus improve power-added efficiency.

In the tracker circuit 1, the input terminals included in the switched-capacitor circuit 20 include three or more input terminals 121 to 126.

The above-mentioned configuration allows for an increased number of available input terminals to which the input voltage (Vin) and the regulated voltage (Vpr) can be respectively input. This configuration enables more suitable discrete voltages (V1 to V6) to be generated in accordance with a radio frequency signal, and thus improve power-added efficiency.

In the tracker circuit 1, the switched-capacitor circuit 20 is configured to generate the discrete voltages (V1 to V6) based on the difference between the input voltage (Vin) and the regulated voltage (Vpr).

According to the above-mentioned configuration, by changing the respective magnitudes of the input voltage (Vin) and the regulated voltage (Vpr), and by changing the input terminals 121 to 126 (the nodes N6 to N1) to which these voltages are to be respectively input, the interval between the discrete voltages (V1 to V6) to be generated by the switched-capacitor circuit 20 can be reduced. For example, a large number of voltage levels can be set within the high occurrence frequency range. As a result, a more suitable power supply voltage can be supplied to the power amplifier 2 in accordance with the power of the radio frequency signal. This configuration improves power-added efficiency.

In the tracker circuit 1, the discrete voltages (V1 to V6) include the first output voltage based on the input voltage (Vin), the second output voltage based on the regulated voltage (Vpr), and the third output voltage based on the difference between the input voltage (Vin) and the regulated voltage (Vpr).

According to the above-mentioned configuration, of the first to third output voltages, only the third output voltage may need to be generated based on the difference between the first input voltage and the second input voltage. This configuration reduces the power consumption required to generate the first output voltage and the second output voltage, and thus generate the discrete voltages in a more stable manner.

In the tracker circuit 1, the third output voltage is higher than one of the input voltage (Vin) or the regulated voltage (Vpr), and lower than the other one of the input voltage (Vin) or the regulated voltage (Vpr).

The above-mentioned configuration allows for improved efficiency of the switched-capacitor circuit 20, and more stable generation of the discrete voltages (V1 to V6).

In the tracker circuit 1, the selector switch circuit 40 is configured to select, from among the input terminals 121 to 126, an input terminal that receives at least one of the input voltage (Vin) or the regulated voltage (Vpr), based on the magnitude of the input voltage (Vin).

According to the above-mentioned configuration, even when the input voltage (Vin) vanes, an operation that allows the variation to be absorbed is possible. This configuration enables the discrete voltages (V1 to V6) to stabilize. Therefore, the power-added efficiency of the power amplifier 2 is improved.

In the tracker circuit 1, the selector switch circuit 40 is configured to select, from among the input terminals 121 to 126, an input terminal that receives at least one of the input voltage (Vin) or the regulated voltage (Vpr), based on the difference between the input voltage (Vin) and the regulated voltage (Vpr).

According to the above-mentioned configuration, for example, even when the magnitude relationship between the input voltage (Vin) and the regulated voltage (Vpr) is reversed as the input voltage (Vin) varies, the discrete voltages (V1 to V6) can be stabilized. Therefore, the power-added efficiency of the power amplifier 2 is improved.

In the tracker circuit 1, the supply modulator 30 is configured to select at least one of the discrete voltages (V1 to V6) in accordance with the parallel data signal. The selector switch circuit 40 is configured to select two of the input terminals 121 to 126 in accordance with the serial data signal.

According to the above-mentioned configuration, the supply modulator 30 can be operated at a higher speed than the selector switch circuit 40. The above-mentioned configuration therefore allows for improved envelope tracking of the power supply voltage to be supplied to the power amplifier 2, and improved power-added efficiency. The above-mentioned configuration also reduces high-speed switching of connections between terminals in the selector switch circuit 40, and thus reduces high-speed switching of nodes to which the input voltage (Vin) and the regulated voltage (Vpr) are to be respectively input. This configuration allows the discrete voltages (V1 to V6) from the switched-capacitor circuit 20 to stabilize, which improves power-added efficiency.

In the tracker circuit 1, the pre-regulator circuit 10 is a step-up/down converter circuit.

According to the above-mentioned configuration, the pre-regulator circuit 10 is configured to generate a suitable regulated voltage (Vpr), irrespective of whether the input voltage (Vin) is greater than the regulated voltage (Vpr) or the input voltage (Vin) is less than the regulated voltage (Vpr).

The communication device 7 according to Embodiment 1 includes the tracker circuit 1, the RFIC 5, and the radio frequency circuit 4. The RFIC 5 is configured to process a radio frequency signal. The radio frequency circuit 4 includes the power amplifier 2 and is configured to transmit the radio frequency signal between the RFIC 5 and the antenna 6.

The above-mentioned configuration provides the communication device 7 that improves power-added efficiency, as with the tracker circuit 1 described above.

The voltage supply method according to Embodiment 1 includes converting the input voltage (Vin) into the regulated voltage (Vpr) (S10); selecting one of the input terminals 121 to 126 of the switched-capacitor circuit 20 and outputting the input voltage (Vin) to the one of the input terminals 121 to 126, and selecting another one of the input terminals 121 to 126 and outputting the regulated voltage (Vpr) to the other one of the input terminals 121 to 126 (S20); by the switched-capacitor circuit 20, generating the discrete voltages (V1 to V6) based on the input voltage (Vin) and the regulated voltage (Vpr) (S30); and selectively outputting at least one of the discrete voltages (V1 to V6) to the power amplifier 2 (S40).

The above-mentioned configuration improves power-added efficiency, as with the tracker circuit 1 described above.

### Exemplary Embodiment 2

Exemplary Embodiment 2 will now be described.

Embodiment 2 differs from Embodiment 1 mainly in that the pre-regulator circuit is a step-down converter circuit (buck converter circuit). The following description focuses mainly on differences from Embodiment 1, and descriptions of features common to Embodiment 1 are omitted or simplified.

The communication device 7 according to Embodiment 2 is similar to the communication device 7 according to Embodiment 1 except that the communication device 7 according to Embodiment 2 includes a tracker circuit 1A instead of the tracker circuit 1, and therefore will be neither illustrated nor described in further detail.

### 2.1 Circuit Configuration of Tracker Circuit 1A

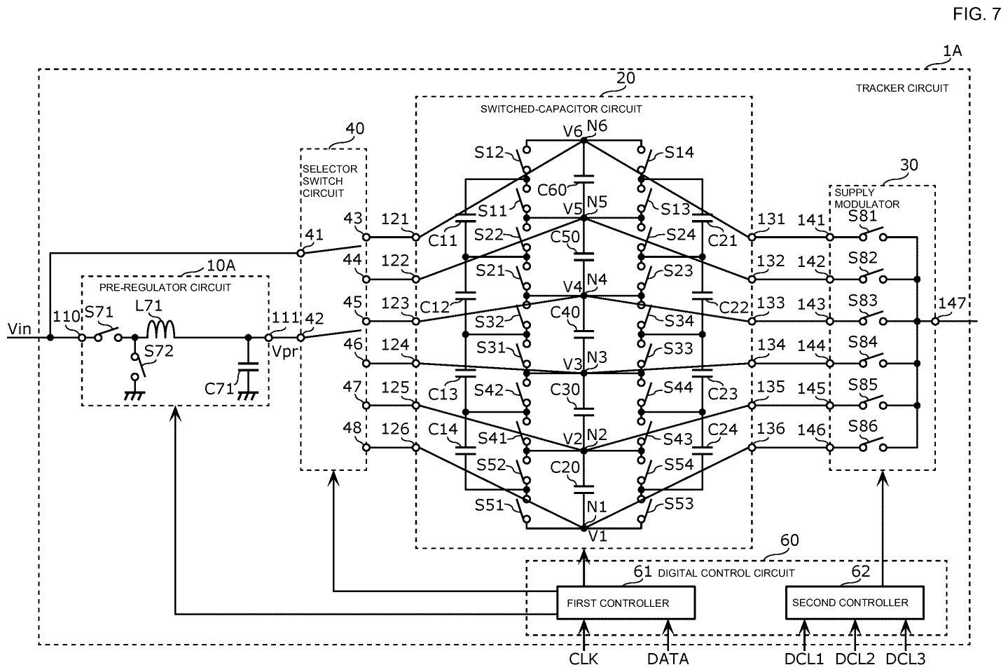

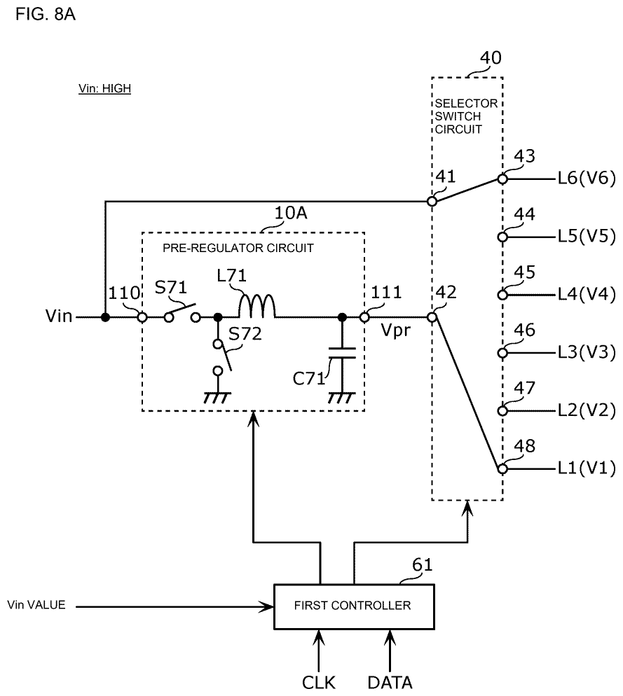

FIG. 7 is a circuit diagram of the tracker circuit 1A according to Embodiment 2. FIG. 7 illustrates an exemplary circuit configuration. The tracker circuit 1A may be implemented by using any one of a wide variety of circuit implementations and circuit technologies. Therefore, the description of the tracker circuit 1A provided below is not to be construed restrictively.

As illustrated in FIG. 7, the tracker circuit 1A is similar to the tracker circuit 1 according to Embodiment 1, except that the tracker circuit 1A includes a pre-regulator circuit 10A instead of the pre-regulator circuit 10.

The pre-regulator circuit 10A is an example of a converter circuit. The pre-regulator circuit 10A may sometimes be also referred to as “magnetic regulator” or “DC-DC converter”. The pre-regulator circuit 10A is configured to convert the input voltage (Vin) into the regulated voltage (Vpr). According to Embodiment 2, the pre-regulator circuit 10A is a one-input, one-output buck converter. The pre-regulator circuit 10A is configured to receive the output voltage from the DC power source 50 as the input voltage, convert the received input voltage into the regulated voltage that is lower than the input voltage, and output the resulting regulated voltage as the input voltage for the selector switch circuit 40. The pre-regulator circuit 10A is configured to vary the magnitude of the regulated voltage based on, for example, a control signal provided from the RFIC 5.

As illustrated in FIG. 7, the pre-regulator circuit 10A includes the input terminal 110, the output terminal 111, the switches S71 and S72, the power inductor L71, and the capacitor C71. The pre-regulator circuit 10A has a circuit configuration such that the switches S73 and S74 are removed from the circuit configuration of the pre-regulator circuit 10 illustrated in FIG. 3. Specifically, the other end of the power inductor L71 is connected to the output terminal 111 and the one of the two electrodes of the capacitor C71, with no switch interposed therebetween. The connection configurations for other components are similar to those in the pre-regulator circuit 10, and therefore will not be described in further detail.

In the tracker circuit 1A according to Embodiment 2, the pre-regulator circuit 10A is a step-down converter circuit, and thus the regulated voltage (Vpr) is lower than the input voltage (Vin). As a result, the pre-regulator circuit 10A is unable to generate the regulated voltage (Vpr) that is higher than the input voltage (Vin). Even in this case, changing the connection configurations for the input terminals 41 and 42 by the selector switch circuit 40 enables operation with stable discrete voltages irrespective of the variation of the input voltage (Vin).

### 2.2 Example of Operation of Selector Switch Circuit 40 and Pre-Regulator Circuit 10A

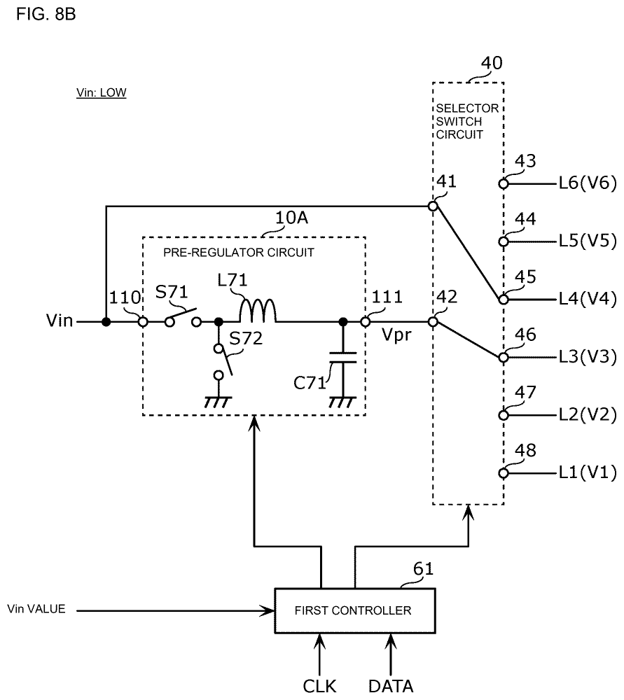

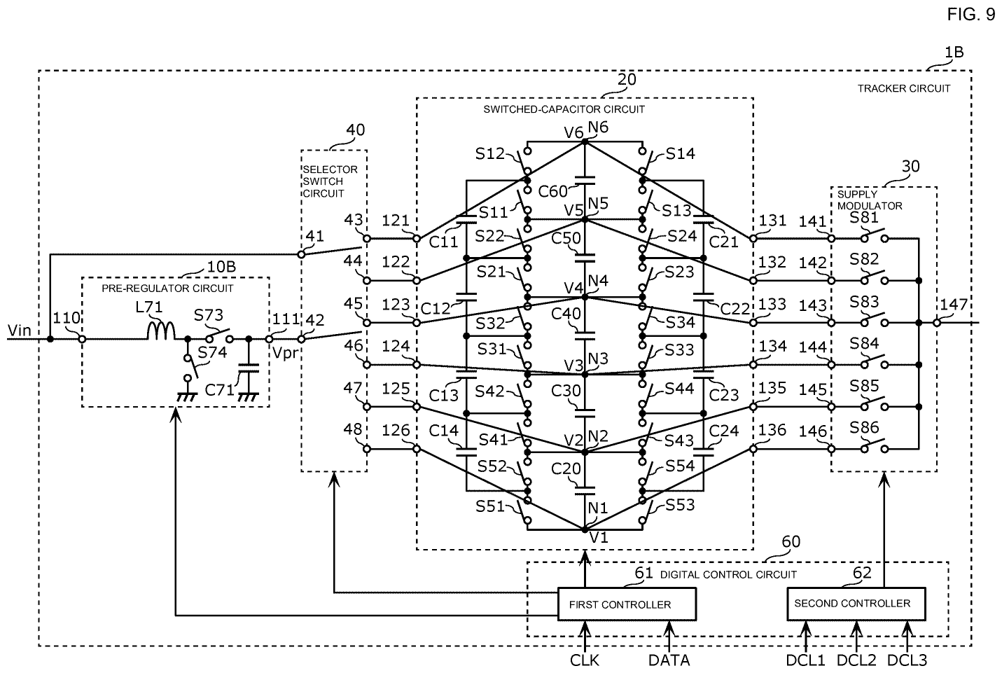

A specific example of operation of the selector switch circuit 40 and the pre-regulator circuit 10A will now be described with reference to FIG. 8A and FIG. 8B.

FIG. 8A and FIG. 8B are circuit diagrams each illustrating an example of a connection configuration for the selector switch circuit 40 according to Embodiment 2. FIG. 8A and FIG. 8B each illustrate, among the components of the tracker circuit 1A illustrated in FIG. 7, only the pre-regulator circuit 10A, the selector switch circuit 40, and the first controller 61 of the digital control circuit 60.

According to the present example of operation, as with the first example of operation according to Embodiment 1, the selector switch circuit 40 is configured to select, from among the input terminals 121 to 126 of the switched-capacitor circuit 20, an input terminal to which at least one of the input voltage (Vin) or the regulated voltage (Vpr) is to be output, based on the magnitude of the output voltage from the DC power source 50, that is, based on the magnitude of the input voltage (Vin) for the tracker circuit 1A. Specifically, the selector switch circuit 40 is configured to select, from among the input terminals 121 to 126 of the switched-capacitor circuit 20, an input terminal to which at least one of the input voltage (Vin) or the regulated voltage (Vpr) is to be output, based on the result of comparison between the input voltage (Vin) and a threshold. More specifically, the selector switch circuit 40 changes the connection configuration for each of the input terminals 41 and 42 with respect to the output terminals 43 to 48, based on the magnitude relationship between the input voltage (Vin) and the threshold.

For example, the first controller 61 compares the detected magnitude of the input voltage (Vin) with the threshold. The threshold is a predetermined fixed value, which is stored in, for example, a memory of the first controller 61. Alternatively, the threshold may be variable depending on, for example, characteristics (e.g., average power) of a radio frequency signal. Further, a plurality of different thresholds may be provided. Based on the result of the comparison, the first controller 61 outputs a control signal to each of the pre-regulator circuit 10A and the selector switch circuit 40.

When the input voltage (Vin) is higher than the threshold, then based on the control signal from the first controller 61, the selector switch circuit 40 connects the input terminal 41 to one of the output terminals 43 to 48 that has a higher voltage level than an output terminal to which the input terminal 42 is to be connected. For example, as illustrated in FIG. 8A, the input terminal 42 is connected to the output terminal 48 corresponding to the level L1, and the input terminal 41 is connected to the output terminal 43 corresponding to the level L6, which is higher than the level L1.

At this time, based on the control signal from the first controller 61, the pre-regulator circuit 10A converts the input voltage (Vin) into the regulated voltage (Vpr) that is lower than the input voltage (Vin), and outputs the resulting regulated voltage (Vpr) from the output terminal 111. The magnitude of the regulated voltage (Vpr) is, for example, determined based on values such as the average power and the peak power of the radio frequency signal.

In the example in FIG. 8A, the input voltage (Vin) is used to support the peak power. However, when the input voltage (Vin) drops, it may become impossible to support the peak power. For example, when the input voltage (Vin) is lower than the threshold, the selector switch circuit 40 lowers the level of an output terminal to which the input terminal 41 is to be connected. For example, as illustrated in FIG. 8B, the input terminal 41 is connected to the output terminal 45 corresponding to the level L4, which is lower than the level L6. Further, the input terminal 42 is connected to the output terminal 46 corresponding to the level L3. Although the output terminal to which to connect the input terminal 42 is also changed in this case, the input terminal 42 may remain connected to the output terminal 48.

As the input terminal 41 is connected to the output terminal 45, the input voltage (Vin) is input to the node N4. In the switched-capacitor circuit 20, the nodes N5 and N6 are each maintained at a higher potential than the node N4. Accordingly, voltages (V5 and V6) higher than the input voltage (Vin) are output from the output terminals 132 and 131 connected to the nodes N5 and N6, respectively.

As described above, according to the present operation example, even when the input voltage (Vin) drops, the output terminal to which to connect the input terminal 41 is changed to an output terminal at a lower level. This configuration allows the discrete voltages (V1 to V6) output from the switched-capacitor circuit 20 to include a voltage higher than the input voltage (Vin). This in turn allows the discrete voltages (V1 to V6) to be generated and output in a stable manner irrespective of the variation of the input voltage (Vin).

At this time, increasing the difference between the regulated voltage (Vpr) to be generated by the pre-regulator circuit 10A and the input voltage (Vin) makes it possible to generate, as one of the discrete voltages (V1 to V6), a voltage further raised relative to the input voltage (Vin). In another configuration, the difference in level between the node to which the regulated voltage (Vpr) is to be input, and the node to which the input voltage (Vin) is to be input may be decreased. In another configuration, the node to which the input voltage (Vin) is to be input may be changed to a node at a lower level. The configurations mentioned above allow the switched-capacitor circuit 20 to generate a further raised voltage as one of the discrete voltages (V1 to V6).

The above-mentioned changing of operation of the pre-regulator circuit 10A, and the above-mentioned changing of a connection configuration for the selector switch circuit 40 are executed, for example, in units of one frame or in larger units. Ensuring that these changing processes are not executed at high speed allows for stable operation of the switched-capacitor circuit 20.

Although the foregoing description of the present operation example is directed to the case where the first controller 61 acquires the Vin value, this is not intended to be limiting. Alternatively, the RFIC 5 may acquire the Vin value, and control operation of the pre-regulator circuit 10A and operation of the selector switch circuit 40. The threshold to be used for comparison with the Vin value may be held in the RFIC 5.

### 2.3 Technical Effects

As described above, in the tracker circuit 1A according to Embodiment 2, the pre-regulator circuit 10A is a step-down converter circuit.

According to the configuration mentioned above, the selector switch circuit 40 adjusts which input terminals (nodes) the input voltage (Vin) and the regulated voltage (Vpr) are to be respectively input to. This configuration allows the discrete voltages (V1 to V6) to be generated in a stable manner even when the input voltage (Vin) varies. Therefore, the tracker circuit 1A is configured to allow for improved power-added efficiency. Further, the configuration of the pre-regulator circuit 10A can be simplified. This can contribute to the reduction of the circuit size of the tracker circuit 1A, and the miniaturization of a module that includes the tracker circuit 1A.

### Exemplary Embodiment 3

Exemplary Embodiment 3 will now be described.

Embodiment 3 differs from Embodiment 1 mainly in that the pre-regulator circuit is a step-up converter circuit (boost converter circuit). The following description focuses mainly on differences from Embodiment 1, and descriptions of features common to Embodiment 1 are omitted or simplified.

The communication device 7 according to Embodiment 3 is similar to the communication device 7 according to Embodiment 1 except that the communication device 7 according to Embodiment 3 includes a tracker circuit 1B instead of the tracker circuit 1, and therefore will be neither illustrated nor described in further detail.

### 3.1 Circuit Configuration of Tracker Circuit 1B

FIG. 9 is a circuit diagram of the tracker circuit 1B according to Embodiment 3. FIG. 9 illustrates an exemplary circuit configuration. The tracker circuit 1B may be implemented by using any one of a wide variety of circuit implementations and circuit technologies. Therefore, the description of the tracker circuit 1B provided below is not to be construed restrictively.

As illustrated in FIG. 9, the tracker circuit 1B is similar to the tracker circuit 1 according to Embodiment 1, except that the tracker circuit 1B includes a pre-regulator circuit 10B instead of the pre-regulator circuit 10.

The pre-regulator circuit 10B is an example of a converter circuit. The pre-regulator circuit 10B may sometimes be also referred to as “magnetic regulator” or “DC-DC converter”. The pre-regulator circuit 10B is configured to convert the input voltage (Vin) into the regulated voltage (Vpr). According to Embodiment 3, the pre-regulator circuit 10B is a one-input, one-output boost converter. The pre-regulator circuit 10B is configured to receive the output voltage from the DC power source 50 as the input voltage, convert the received input voltage into the regulated voltage that is higher than the input voltage, and output the resulting regulated voltage as the input voltage for the selector switch circuit 40. The pre-regulator circuit 10B is configured to vary the magnitude of the regulated voltage based on, for example, a control signal provided from the RFIC 5.

As illustrated in FIG. 9, the pre-regulator circuit 10B includes the input terminal 110, the output terminal 111, the switches S73 and S74, the power inductor L71, and the capacitor C71. The pre-regulator circuit 10B has a circuit configuration such that the switches S71 and S72 are removed from the circuit configuration of the pre-regulator circuit 10 illustrated in FIG. 3. Specifically, the one end of the power inductor L71 is connected to the input terminal 110 with no switch interposed therebetween. The connection configurations for individual components are similar to those in the pre-regulator circuit 10, and therefore will not be described in further detail.

In the tracker circuit 1B according to Embodiment 3, the pre-regulator circuit 10B is a step-up converter circuit, and thus the regulated voltage (Vpr) is higher than the input voltage (Vin). As a result, the pre-regulator circuit 10B is unable to generate the regulated voltage (Vpr) that is lower than the input voltage (Vin). Even in this case, changing the connection configurations for the input terminals 41 and 42 by the selector switch circuit 40 enables operation with stable discrete voltages irrespective of the variation of the input voltage (Vin).

### 3.2 Example of Operation of Selector Switch Circuit 40 and Pre-Regulator Circuit 10B

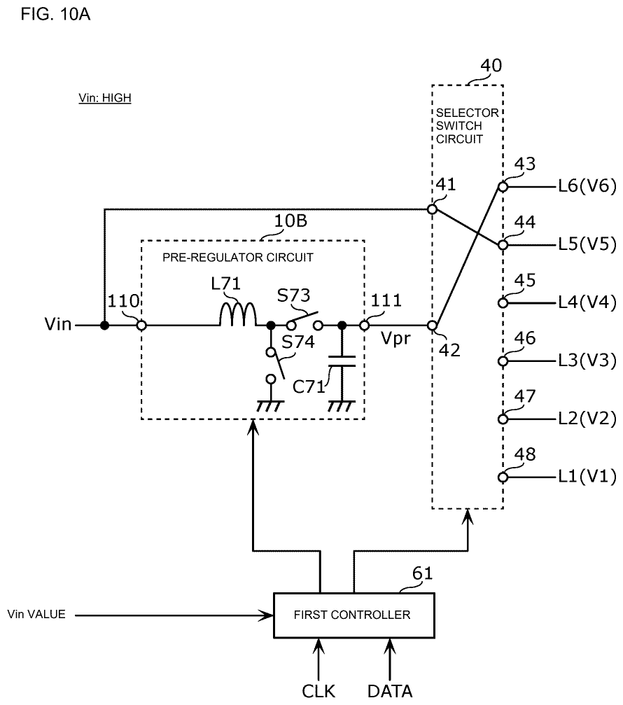

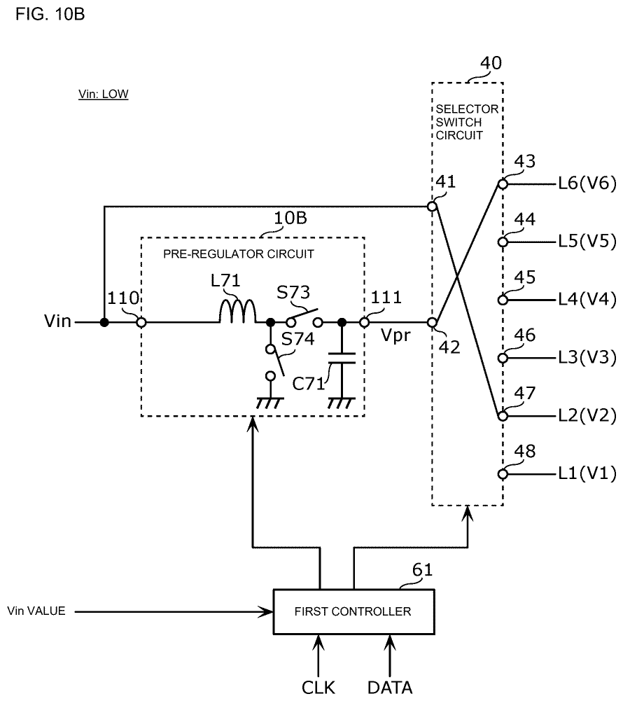

A specific example of operation of the selector switch circuit 40 and the pre-regulator circuit 10B will now be described with reference to FIG. 10A and FIG. 10B.

FIG. 10A and FIG. 10B are circuit diagrams each illustrating an example of a connection configuration for the selector switch circuit 40 according to Embodiment 3. FIG. 10A and FIG. 10B each illustrate, among the components of the tracker circuit 1B illustrated in FIG. 9, only the pre-regulator circuit 10B, the selector switch circuit 40, and the first controller 61 of the digital control circuit 60.

According to the present example of operation, as with the first example of operation according to Embodiment 1, the selector switch circuit 40 is configured to select, from among the input terminals 121 to 126 of the switched-capacitor circuit 20, an input terminal to which at least one of the input voltage (Vin) or the regulated voltage (Vpr) is to be output, based on the magnitude of the output voltage from the DC power source 50, that is, based on the magnitude of the input voltage (Vin) for the tracker circuit 1B. Specifically, the selector switch circuit 40 is configured to select, from among the input terminals 121 to 126 of the switched-capacitor circuit 20, an input terminal to which at least one of the input voltage (Vin) or the regulated voltage (Vpr) is to be output, based on the result of comparison between the input voltage (Vin) and a threshold. More specifically, the selector switch circuit 40 changes the connection configuration for each of the input terminals 41 and 42 with respect to the output terminals 43 to 48, based on the magnitude relationship between the input voltage (Vin) and the threshold.

For example, the first controller 61 compares the detected magnitude of the input voltage (Vin) with the threshold. The threshold is a predetermined fixed value, which is stored in, for example, a memory of the first controller 61. Alternatively, the threshold may be variable depending on, for example, characteristics (e.g., average power) of a radio frequency signal. Further, a plurality of different thresholds may be provided. Based on the result of the comparison, the first controller 61 outputs a control signal to each of the pre-regulator circuit 10B and the selector switch circuit 40.

When the input voltage (Vin) is higher than the threshold, then based on the control signal from the first controller 61, the selector switch circuit 40 connects the input terminal 41 to one of the output terminals 43 to 48 that has a lower voltage level than an output terminal to which the input terminal 42 is to be connected. For example, as illustrated in FIG. 10A, the input terminal 42 is connected to the output terminal 43 corresponding to the level L6, and the input terminal 41 is connected to the output terminal 44 corresponding to the level L5, which is lower than the level L6.

At this time, based on the control signal from the first controller 61, the pre-regulator circuit 10B converts the input voltage (Vin) into the regulated voltage (Vpr) that is higher than the input voltage (Vin), and outputs the resulting regulated voltage (Vpr) from the output terminal 111. The magnitude of the regulated voltage (Vpr) is, for example, determined based on values such as the average power and the peak power of the radio frequency signal.

In the example in FIG. 10A, the regulated voltage (Vpr) is used to support the peak power. Further, by reducing the difference in level (which is 1 in this case) between two nodes to which the regulated voltage (Vpr) and the input voltage (Vin) are to respectively input, a voltage (e.g., V1) corresponding to a low level among the discrete voltages (V1 to V6) can be further reduced in magnitude. Consequently, even when the input voltage (Vin) is high, a voltage corresponding to a low level can be generated.

When the input voltage (Vin) drops, for example, when the input voltage (Vin) is lower than the threshold, the selector switch circuit 40 lowers the level of an output terminal to which the input terminal 41 is to be connected. For example, as illustrated in FIG. 10B, the input terminal 41 is connected to the output terminal 47 corresponding to the level L2, which is lower than the level L5. Although the output terminal to which to connect the input terminal 42 remains unchanged in this case, the input terminal 42 may be connected to an output terminal different from the output terminal 43. Even when the input voltage (Vin) drops, the pre-regulator circuit 10B is configured to generate a high regulated voltage (Vpr) through step-up operation.

As described above, according to the present operation example, even when the input voltage (Vin) varies, adjusting to which output terminal the input terminal 41 is to be connected allows the discrete voltages (V1 to V6) output from the switched-capacitor circuit 20 to include a voltage higher than the input voltage (Vin) and a voltage lower than the input voltage (Vin). This in turn allows the discrete voltages (V1 to V6) to be generated and output in a stable manner irrespective of the variation of the input voltage (Vin).

For example, when the input voltage (Vin) is high, increasing the difference between the regulated voltage (Vpr) to be generated by the pre-regulator circuit 10B and the input voltage (Vin) makes it possible to generate, as one of the discrete voltages (V1 to V6), a voltage further lowered relative to the input voltage (Vin). In another configuration, the difference in level between the node to which the regulated voltage (Vpr) is to be input, and the node to which the input voltage (Vin) is to be input may be decreased. In another configuration, the node to which the input voltage (Vin) is to be input may be changed to a node at a higher level. The configurations mentioned above allow the switched-capacitor circuit 20 to generate a further lowered voltage as one of the discrete voltages (V1 to V6).

The above-mentioned changing of operation of the pre-regulator circuit 10B, and the above-mentioned changing of a connection configuration for the selector switch circuit 40 are executed, for example, in units of one frame or in larger units. Ensuring that these changing processes are not executed at high speed allows for stable operation of the switched-capacitor circuit 20.

Although the foregoing description of the present operation example is directed to the case where the first controller 61 acquires the Vin value, this is not intended to be limiting. Alternatively, the RFIC 5 may acquire the Vin value, and control operation of the pre-regulator circuit 10B and operation of the selector switch circuit 40. The threshold to be used for comparison with the Vin value may be held in the RFIC 5.

### 3.3 Technical Effects

As described above, in the tracker circuit 1B according to Embodiment 3, the pre-regulator circuit 10B is a step-down converter circuit.

According to the configuration mentioned above, the selector switch circuit 40 adjusts which input terminals (nodes) the input voltage (Vin) and the regulated voltage (Vpr) are to be input to. This configuration allows the discrete voltages (V1 to V6) to be generated in a stable manner even when the input voltage (Vin) varies. Therefore, the tracker circuit 1B is configured to allow for improved power-added efficiency. Further, the configuration of the pre-regulator circuit 10B can be simplified. This can contribute to the reduction of the circuit size of the tracker circuit 1B, and the miniaturization of a module that includes the tracker circuit 1B.

### (Configuration of Integrated Circuit)

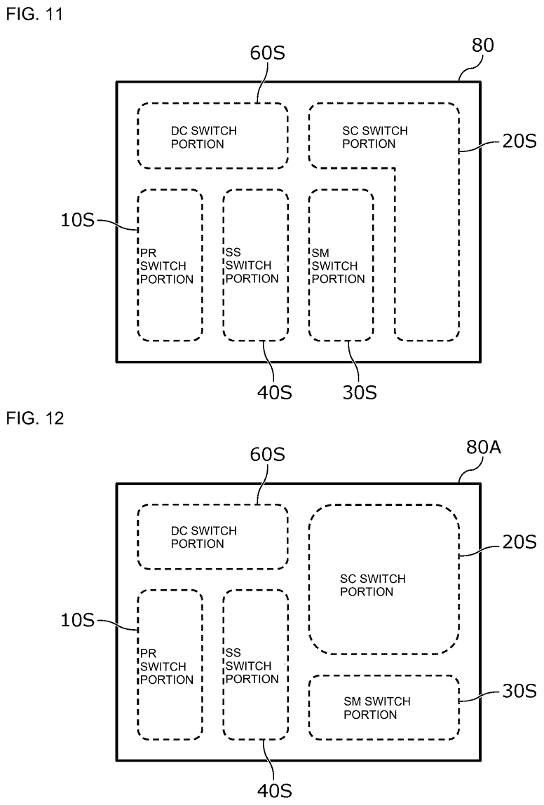

An integrated circuit including part of the circuit configuration of the tracker circuit 1, 1A, or 1B according to the embodiments will now be described with reference to FIG. 11. Specifically, the integrated circuit includes a plurality of switches of the tracker circuit 1, 1A, or 1B.

FIG. 11 is a plan view of an example of arrangement of switch portions included in the tracker circuit 1, 1A, or 1B according to the embodiments. FIG. 11 illustrates an exemplary arrangement. The switch portions included in the tracker circuit 1, 1A, or 1B are implemented by a wide variety of arrangements. Therefore, the description of the arrangement given below is not to be construed restrictively.

An integrated circuit 80 is a semiconductor integrated circuit (IC), and is implemented by using, for example, complementary metal oxide semiconductor (CMOS). Specifically, the integrated circuit 80 may be manufactured by using a Si substrate or a silicon on insulator (SOI) substrate. Alternatively, the integrated circuit 80 may be made of at least one of GaAs, SiGe, or GaN. It should also be appreciated that the semiconductor material of the integrated circuit 80 is not limited to the materials mentioned above as would be understood by one skilled in the art.

The integrated circuit 80 is mounted to a major face of a module laminate (not illustrated). Suitable examples of the module laminate may include: a low temperature co-fired ceramic (LTCC) substrate or a high temperature co-fired ceramic (HTCC) substrate, which has a multilayer structure of a plurality of dielectric layers; a component-embedded substrate; a substrate with a redistribution layer (RDL); and a printed circuit board.

Other than the integrated circuit 80, a surface mount device (SMD) such as a chip capacitor, an integrated passive device (IPD), or other components may be mounted to the module laminate. For example, the capacitors C11 to C15, C21 to C25, C20, C30, C40, C50, C60, and C71 illustrated in FIG. 3 or other figures are implemented as chip capacitors and mounted to the major face of the module laminate.

As illustrated in FIG. 11, the integrated circuit 80 includes a PR switch portion 10S, an SC switch portion 20S, an SM switch portion 30S, an SS switch portion 40S, and a DC switch portion 60S.

The PR switch portion 10S is implemented by switches included in the pre-regulator circuit 10, 10A, or 10B. Specifically, the PR switch portion 10S includes the switches S71 to S74. The PR switch portion 10S may be configured to not include at least one of the switch S71, S72, S73, or S74.

The SC switch portion 20S is implemented by switches included in the switched-capacitor circuit 20. Specifically, the SC switch portion 20S includes the switches S11 to S14, S21 to S24, S31 to S34, S41 to S44, and S51 to S54.

The SM switch portion 30S is implemented by switches included in the supply modulator 30. Specifically, the SM switch portion 30S includes the switches S81 to S84.

The SS switch portion 40S is implemented by switches included in the selector switch circuit 40.

The DC switch portion 60S is implemented by switches included in the digital control circuit 60.

In the example in FIG. 11, the PR switch portion 10S, the SS switch portion 40S, the SM switch portion 30S, and the DC switch portion 60S each have a rectangular shape in plan view. The SS switch portion 40S is disposed between the PR switch portion 10S and the SM switch portion 30S. The DC switch portion 60S is disposed such that the direction of its long side is parallel to the direction of the short side of the PR switch portion 10S.

The SC switch portion 20S is disposed such that in plan view, the SC switch portion 20S has an L-shape extending along the short and long sides of the SM switch portion 30S. The SC switch portion 20S is disposed along the peripheral edges of the integrated circuit 80 in such a way that the wiring distance to capacitors (not illustrated) disposed around the integrated circuit 80 is short. The short wiring distance to the capacitors reduces parasitic capacitance and parasitic inductance.

It is noted that the shape of the SC switch portion 20S in plan view is not limited to the example illustrated in FIG. 11 as would be appreciated to one skilled in the art. For example, FIG. 12 is a plan view of another example of arrangement of switch portions included in the tracker circuit 1, 1A, or 1B according to the embodiments. As illustrated in FIG. 12, the shape of the SC switch portion 20S in plan view may be a rectangle (oblong or square).

In the arrangement in FIG. 12, the PR switch portion 10S, the SS switch portion 40S, and the SC switch portion 20S are arranged in this order. This configuration shortens the wiring distance between the pre-regulator circuit 10, 10A, or 10B, the selector switch circuit 40, and the switched-capacitor circuit 20 within an integrated circuit 80A. This in turn reduces parasitic capacitance and parasitic inductance.

Although FIG. 11 and FIG. 12 both illustrate an example in which the switch portions included in the tracker circuit 1, 1A, or 1B are integrated within a single integrated circuit 80 or 80A, this is not intended to be limiting. The switch portions included in the tracker circuit 1, 1A, or 1B may be disposed in a distributed manner across a plurality of integrated circuits.

### Additional Exemplary Embodiments

Although the tracker circuit, the communication device, and the voltage supply method according to the exemplary aspects of the present disclosure have been described above based on embodiments, the embodiments are not intended to limit the tracker circuit, the communication device, and the voltage supply method described herein. The exemplary aspects of the present disclosure encompasses other embodiments implemented by combining any constituent elements in the above embodiments; modifications obtained by modifying the above embodiments in various ways as may be apparent to those skilled in the art without departing from the scope of the exemplary aspects of the present disclosure; and various devices incorporating the tracker circuit mentioned above.

For example, in the circuit configurations of the various circuits according to the embodiments, another circuit element, wiring, and other features may be inserted between individual circuit elements and paths connecting signal paths disclosed in the drawings. For example, an inductor and/or capacitor may be inserted between the tracker circuit and the power amplifier.

It is noted that the number of discrete voltages to be output by the switched-capacitor circuit according to the exemplary embodiments is not limited to six and may be a different number as would be appreciated to one skilled in the art. For example, the number of discrete voltages to be output by the switched-capacitor circuit may be any plural number, for example, three, four, five, or seven or more. Decreasing the number of discrete voltages simplifies the configuration of the switched-capacitor circuit. This can contribute to miniaturization of the tracker circuit. Increasing the number of discrete voltages improves tracking of the envelope signal. This configuration improves power-added efficiency.

Although the foregoing description is directed to the case where the switched-capacitor circuit according to the embodiments is a differential switched-capacitor circuit, this is not intended to be limiting. The switched-capacitor circuit may be a ladder switched-capacitor circuit in an alternative aspect. For example, the node at the lowest voltage level (e.g., the node N1) may be connected to ground.

In this case, the selector switch circuit is configured to select, as the input voltage to be input to the switched-capacitor circuit, one of the input voltage (Vin) or the regulated voltage (Vpr). The ability to select not only the regulated voltage (Vpr) but also the input voltage (Vin) makes it possible to generate the discrete voltages by use of the input voltage (Vin). Accordingly, in a case where the input voltage (Vin) is used, the pre-regulator circuit 10 can be deactivated. This configuration reduces power consumption and improve power-added efficiency. In this way, power-added efficiency is improved even when the switched-capacitor circuit is not a differential switched-capacitor circuit.

Although the foregoing description is directed to the case where the selector switch circuit according to the embodiments includes the same number of output terminals as the number of nodes (the number of output terminals) of the switched-capacitor circuit, this is not intended to be limiting. The number of output terminals included in the selector switch circuit may be any plural number, for example, two to five, or seven or more. The same applies to the number of input terminals of the switched-capacitor circuit. In this case as well, power-added efficiency is improved.

Other embodiments, such as those obtained by modifying the embodiments in various ways that may be apparent to those skilled in the art, or those implemented through any suitable combination of constituent elements and functions according to the embodiments without departing from the spirit and scope of the exemplary embodiments described herein may also fall within the spirit and scope of the exemplary aspects of the present disclosure.

The exemplary aspects of the present disclosure provide for a wide variety of communication devices such as mobile phones and can be configured as a tracker circuit that supplies voltage to a power amplifier.

### REFERENCE SIGNS LIST

1, 1A, 1B tracker circuit
2 power amplifier
3 filter
4 radio frequency circuit
5 RFIC
6 antenna
7 communication device
10, 10A, 10B pre-regulator circuit
10S PR switch portion
20 switched-capacitor circuit
20S SC switch portion
30 supply modulator
30S SM switch portion
40 selector switch circuit
40S SS switch portion
41, 42, 110, 121, 122, 123, 124, 125, 126, 141, 142, 143, 144, 145, 146 input terminal
43, 44, 45, 46, 47, 48, 111, 131, 132, 133, 134, 135, 136, 147 output terminal
50 DC power source
60 digital control circuit
60S DC switch portion
61 first controller
62 second controller
80, 80A integrated circuit

1. A tracker circuit comprising:
a converter circuit configured to convert an input voltage into a regulated voltage;
a switched-capacitor circuit including a plurality of first input terminals configured to receive the input voltage and the regulated voltage, and further configured to generate a plurality of discrete voltages;
a supply modulator configured to selectively output at least one discrete voltage of the plurality of discrete voltages to a power amplifier; and
a selector switch circuit connected to the converter circuit and the switched-capacitor circuit, the selector switch circuit being configured to select one first input terminal of the plurality of first input terminals and output the input voltage to the selected one first input terminal, and configured to select an other first input terminal of the plurality of first input terminals and to output the regulated voltage to the selected other first input terminal.

2. The tracker circuit according to claim 1, wherein the selector switch circuit includes:
a second input terminal configured to receive the input voltage,
a third input terminal configured to receive the regulated voltage, and
a plurality of output terminals respectively connected to the plurality of first input terminals, and
wherein the second input terminal and the third input terminal are each configured to be selectively connectable to the plurality of output terminals.

3. The tracker circuit according to claim 2, wherein the plurality of first input terminals include three or more first input terminals.

4. The tracker circuit according to claim 1, wherein the switched-capacitor circuit is configured to generate the plurality of discrete voltages based on a difference between the input voltage and the regulated voltage.

5. The tracker circuit according to claim 4, wherein the plurality of discrete voltages include:
a first output voltage based on the input voltage,
a second output voltage based on the regulated voltage, and
a third output voltage based on the difference between the input voltage and the regulated voltage.

6. The tracker circuit according to claim 5, wherein the third output voltage has a voltage value that is between respective voltage values of the input voltage and the regulated voltage.

7. The tracker circuit according to claim 1, wherein the selector switch circuit is configured to select, from among the plurality of first input terminals, a first input terminal that receives at least one of the input voltage or the regulated voltage, based on a magnitude of the input voltage.

8. The tracker circuit according to claim 1, wherein the selector switch circuit is configured to select, from among the plurality of first input terminals, a first input terminal that receives at least one of the input voltage or the regulated voltage, based on a difference between the input voltage and the regulated voltage.

9. The tracker circuit according to claim 1,
wherein the supply modulator is configured to select the at least one discrete voltage in accordance with a parallel data signal, and
wherein the selector switch circuit is configured to select two input terminals of the plurality of first input terminals in accordance with a serial data signal.

10. The tracker circuit according to claim 1, wherein each of the selector switch circuit, the switched-capacitor circuit and the supply modulator include a switch that is included in a same integrated circuit.

11. The tracker circuit according to claim 1, wherein the converter circuit is a step-up/down converter circuit.

12. The tracker circuit according to claim 1, wherein the converter circuit is a step-up converter circuit.

13. The tracker circuit according to claim 1, wherein the converter circuit is a step-down converter circuit.

14. A tracker circuit comprising:
a converter circuit including:
a fourth input terminal configured to receive an input voltage, and
a first output terminal configured to output a regulated voltage generated from the input voltage;
a selector switch circuit including:
a second input terminal connected to the fourth input terminal,
a third input terminal connected to the first output terminal, and
a plurality of second output terminals;
a switched-capacitor circuit including:
a plurality of first input terminals connected respectively to the plurality of second output terminals, and
a plurality of third output terminals that are respectively connected to the plurality of first input terminals, and that are configured to output a plurality of discrete voltages generated based on the input voltage and the regulated voltage; and
a supply modulator including:
a plurality of fifth input terminals respectively connected to the plurality of third output terminals, and
a fourth output terminal connected to a power amplifier.

15. The tracker circuit according to claim 14, wherein the second input terminal and the third input terminal are each configured to be selectively connectable to the plurality of second output terminals.

16. The tracker circuit according to claim 14, wherein the plurality of first input terminals include three or more first input terminals.

17. The tracker circuit according to claim 14, wherein the switched-capacitor circuit is configured to generate the plurality of discrete voltages based on a difference between the input voltage and the regulated voltage.

18. The tracker circuit according to claim 14,
wherein the supply modulator is configured to select at least one discrete voltage of the plurality of discrete voltages in accordance with a parallel data signal, and
wherein the selector switch circuit is configured to select two input terminals of the plurality of first input terminals in accordance with a serial data signal.

19. A communication device comprising:
the tracker circuit according to claim 1;
a signal processing circuit configured to process a radio frequency signal; and
a radio frequency circuit including the power amplifier, the radio frequency circuit being configured to transmit the radio frequency signal between the signal processing circuit and an antenna.

20. A voltage supply method comprising:
converting an input voltage into a regulated voltage;
selecting one input terminal of a plurality of input terminals of a switched-capacitor circuit;
outputting the input voltage to the selected one input terminal;
selecting an other input terminal of the plurality of input terminals;
outputting the regulated voltage to the selected other input terminal;
generating, by the switched-capacitor circuit, a plurality of discrete voltages based on the input voltage and the regulated voltage; and
selectively outputting at least one discrete voltage of the plurality of discrete voltages to a power amplifier.
